(19) United States
(12) Patent Application Publication
(10) Pub. No.: US 2024/0292605 A1
(43) Pub. Date: Aug. 29, 2024

(54) SEMICONDUCTOR DEVICE AND METHOD FOR FABRICATING THE SAME

(71) Applicant: SK hynix Inc., Gyeonggi-do (KR)

(72) Inventors: Il Do KIM, Gyeonggi-do (KR); Seung Mi YEO, Gyeonggi-do (KR); Seung Bum KIM, Gyeonggi-do (KR)

(21) Appl. No.: 18/457,337

(22) Filed: Aug. 29, 2023

(30) Foreign Application Priority Data
Feb. 28, 2023 (KR) 10-2023-0026711

(51) Int. Cl. H10B 12/00

(52) U.S. Cl. CPC H10B 12/488; H10B 12/03; H10B 12/05

(57) ABSTRACT

The semiconductor device include a horizontal layer spaced apart from a lower structure to extend along a direction parallel to the lower structure; a first conductive line extending along a direction perpendicular to the lower structure and coupled to one end of the horizontal layer; a data storage element coupled to the other end of the horizontal layer; and a second conductive line extending along a direction across the horizontal layer, wherein the second conductive line comprises: a high work function electrode; and a low work function electrode having a cup shape laterally oriented and disposed adjacent to the first conductive line and having a lower work function than the high work function electrode.

### CROSS-REFERENCE TO RELATED APPLICATION

This application claims priority under 35 U.S.C. § 119 to Korean Patent Application No. 10-2023-0026711 filed on Feb. 28, 2023, which is incorporated herein by reference in its entirety.

### BACKGROUND

### 1. Field

Embodiments relate to a semiconductor device, and more particularly, to a semiconductor device including three-dimensional (3D) memory cells and a method for fabricating the same.

### 2. Discussion of the Related Art

Recently, in order to cope with an increase in capacity and miniaturization of a memory device, a technology providing a three-dimensional (3-D) memory device in which a plurality of memory cells are stacked has been proposed. At present extensive research and development efforts are directed to improving reliability and performance of 3-D semiconductor devices.

### SUMMARY

Various embodiments of the present disclosure are directed to providing a 3-D semiconductor device (hereinafter simply referred to simply as semiconductor device) including highly integrated memory cells and a method for fabricating the same.

A semiconductor device in accordance with an embodiment of the present disclosure may include: a horizontal layer spaced apart from a lower structure to extend along a direction parallel to the lower structure; a first conductive line extending along a direction perpendicular to the lower structure and coupled to one end of the horizontal layer; a data storage element coupled to the other end of the horizontal layer; and a second conductive line extending along a direction across the horizontal layer, wherein the second conductive line comprises a high work function electrode; and a low work function electrode having a cup shape laterally oriented and positioned adjacent to the first conductive line and having a lower work function than the high work function electrode.

A method for fabricating a semiconductor device in accordance with an embodiment of the present disclosure may include: forming a stack body in which an insulating layer, a first sacrificial layer, a semiconductor layer, and a second sacrificial layer are alternately stacked above a lower structure; forming a vertical opening by etching the stack body; forming horizontal recesses by recessing the first sacrificial layer and the second sacrificial layer from the vertical opening; forming a horizontal conductive line including a combination of different work function electrodes in the horizontal recesses; and forming a vertical conductive line in the vertical opening, wherein the forming of the horizontal conductive line comprises: forming a first cup-shape low work function electrode; forming a high work function electrode on a side surface of the first low work function electrode; and forming a second cup-shape low work function electrode on a side surface of the high work function electrode, the second low work function electrode being opposed to the first conductive line. The method further comprises forming a first barrier layer on an inner surface of the first cup-shape low work function electrode; forming a second barrier layer between the high work function electrode and the first cup-shape low work function electrode; and forming a third barrier layer between the high work function electrode and the second cup-shape low work function electrode. The second barrier layer covers a part of the high work function electrode. Each of the first and second cup-shape low work function electrodes includes N-type dopant doped polysilicon. The high work function electrode includes a metal-base material. The method further comprising, after the forming of the vertical conductive line: forming a data storage element coupled to the other end of the horizontal layer.

A semiconductor device in accordance with another embodiment of the present disclosure may include: a first conductive line extending along a first direction above a lower structure; a horizontal layer spaced apart from the lower structure and extending laterally from a first end thereof that contacts the first conductive line along a second direction that is parallel to the lower structure; a data storage element in contact to a second end of the horizontal layer; and a second conductive line extending along a third direction across the horizontal layer, wherein the second conductive line comprises a high work function electrode; and a first cup shape-low work function electrode adjacent to the data storage element and having a lower work function than the high work function electrode; and a second cup-shape low work function electrode adjacent to the first conductive line and having a lower work function than the high work function electrode. The semiconductor device further comprises a first barrier layer disposed on an inner surface of the first cup-shape low work function electrode; a second barrier layer between the first cup-shape low work function electrode and the high work function electrode; and a third barrier layer between the high work function electrode and the second cup-shape low work function electrode. The second barrier layer partially surrounds the high work function electrode. The semiconductor device further comprises a gap-fill material disposed on an inner surface of the first cup-shape low work function electrode. The first and second cup-shape low work function electrodes each have a work function lower than the mid-gap work function of silicon, and the high work function electrode has a work function higher than the mid-gap work function of the silicon. The first and second cup-shape low work function electrodes each include N-type dopant doped polysilicon. The high work function electrode includes a metal-base material. The high work function electrode includes metal, metal nitride, or a combination thereof. The high work function electrode has a larger volume than the first and second cup-shape low work function electrodes. Each of the high work function electrode and the first and second cup-shape low work function electrodes vertically overlaps the horizontal layer. The first cup-shape low work function electrode and the second cup-shape low work function electrode have substantially the same work function. The horizontal layer has a smaller thickness than the high work function electrode and the first and second cup-shape low work function electrodes. The horizontal layer includes a single crystal semiconductor material, a polycrystalline semiconductor material, or an oxide semiconductor material. The horizontal layer comprises a first doped region coupled to the first conductive line; a second doped region coupled to the data storage element; and a channel between the first doped region and the second doped region. The second conductive line includes a double structure and opposed to each other with the horizontal layer interposed therebetween. The data storage element includes a capacitor, and the capacitor includes a cylindrical first electrode, a second electrode, and a dielectric layer between the first electrode and the second electrode. The first cup-shape low work function electrode includes a first inner surface opposed to the high work function electrode and a first outer surface opposed to the data storage element, and the second cup-shape low work function electrode includes a second outer surface opposed to the high work function electrode and a second inner surface opposed to the first conductive line. The first cup-shape low work function electrode includes a first outer surface opposed to the high work function electrode and a first inner surface opposed to the data storage element, and the second cup-shape low work function electrode includes a second outer surface opposed to the high work function electrode and a second inner surface opposed to the first conductive line. The semiconductor device further comprises a gap-fill material disposed inside each of the first inner surface of the first low work function electrode and the second inner surface of the second low work function electrode. The semiconductor device further comprises a gate dielectric layer fully covering each of an upper surface and a lower surface of the horizontal layer.

According to the present technology, high integration of memory cells can be implemented by forming a word line having a triple electrode structure.

The present technology can improve leakage current by forming a word line having a triple electrode structure, and thereby secures refresh characteristics, enabling low power consumption with low power consumption.

The present technology is relatively advantageous in increasing an electric field generated when a channel thickness is reduced for high integration, and thus is advantageous for high integration through implementation of a high number of stacked layers.

The present technology can form a barrier layer between a high work function electrode and a low work function electrode, thereby improving electrical characteristics of a word line.

The present technology can achieve low power consumption and high integration of three-dimensional memory cells.

### BRIEF DESCRIPTION OF THE DRAWINGS

FIG. 1A is a simplified schematic perspective view of a memory cell in accordance with an embodiment.

FIG. 1B is a simplified schematic cross-sectional view of the memory cell in FIG. 1A.

FIG. 1C is an enlarged view of the first work function electrode shown in FIG. 1B.

FIG. 1D is an enlarged view of the third work function electrode shown in FIG. 1B.

FIG. 2A is a simplified schematic plan view of a semiconductor device.

FIG. 2B is a cross-sectional view taken along line A-A′ in FIG. 2A.

FIG. 3 to FIG. 21 are views for explaining an example of a method for fabricating a semiconductor device in accordance with an embodiment.

FIG. 22 is a simplified schematic cross-sectional view of a memory cell in accordance with another embodiment.

FIG. 23 to FIG. 40 are views for explaining an example of a method for fabricating a semiconductor device in accordance with another embodiment.

FIG. 41 is a simplified schematic cross-sectional view of a memory cell in accordance with another embodiment.

### DETAILED DESCRIPTION

Embodiments described herein will be described with reference to cross-sectional views, plan views, and block diagrams, which are ideal schematic diagrams of the present disclosure. Accordingly, the shapes of the illustrative drawings may be modified due to manufacturing techniques and/or tolerances. Accordingly, embodiments of the present disclosure are not limited to the illustrated specific shapes, and also include changes in shapes generated according to fabrication processes. Accordingly, regions illustrated in the drawings have schematic attributes, and the shapes of the regions illustrated in the drawings are intended to illustrate a specific shape of a region of a device and are not intended to limit the scope of the disclosure.

Embodiments to be described below can increase memory cell density and reduce parasitic capacitance by vertically stacking memory cells.

Embodiments to be described below relate to a three-dimensional memory cell, and a second conductive line (word line or gate electrode) may include a low work function electrode and a high work function electrode. The low work function electrode may be adjacent to a data storage element (for example, capacitor) and a first conductive line (or bit line), and the high work function electrode may overlap a channel of a lateral layer.

A low electric field can be formed between the second conductive line and the data storage element due to a low work function of the low work function electrode, thereby making it possible to reduce leakage current.

A high threshold voltage of a switch element can be formed due to a high work function of the high work function electrode, and the height of a memory cell can be lowered due to formation of a low electric field, which is advantageous in terms of integration.

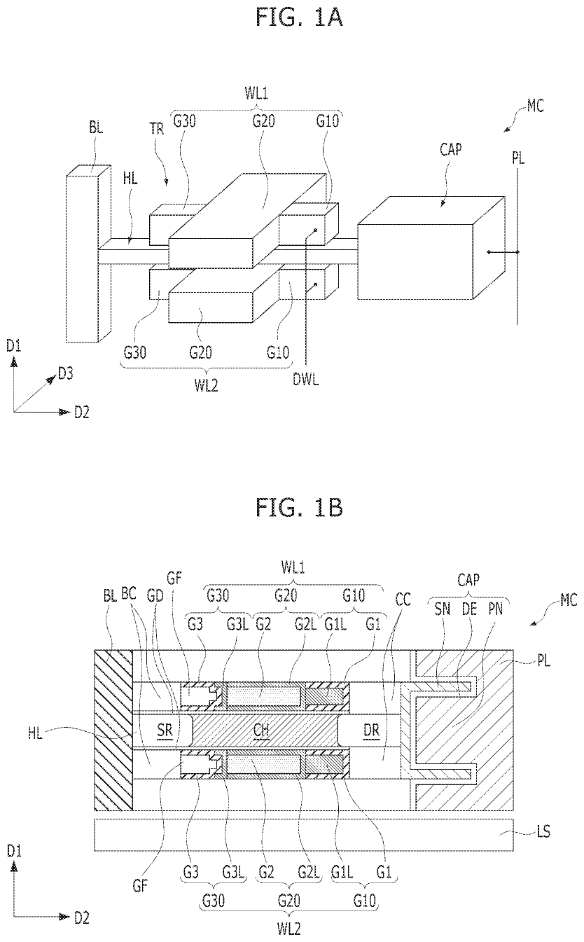

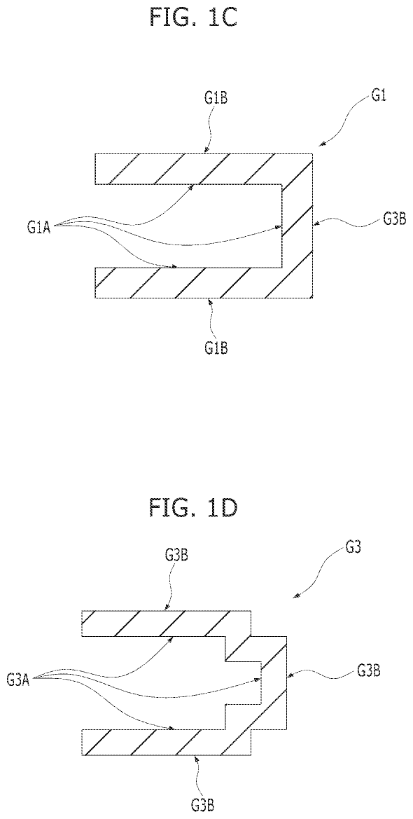

FIG. 1A is a simplified schematic perspective view of a memory cell MC in accordance with an embodiment. FIG. 1B is a simplified schematic cross-sectional view of the memory cell MC in FIG. 1A. FIG. 1C is an enlarged view of the first work function electrode shown in FIG. 1B. FIG. 1D is an enlarged view of the third work function electrode shown in FIG. 1B.

Referring to FIG. 1A and FIG. 1B, the memory cell MC may include a first conductive line BL, a switch element TR, and a data storage element CAP. The switch element TR may include a horizontal layer HL, a gate dielectric layer GD, and a second conductive line DWL. The data storage element CAP may be a memory element such as a capacitor. The first conductive line BL may be a bit line. The second conductive line DWL may be a word line, and the horizontal layer HL may be an active layer. The data storage element CAP may include a first electrode SN, a second electrode PN, and a dielectric layer DE positioned between the first and second electrodes SN and PN. In some embodiments, the switch element TR may include a transistor, and the second conductive line DWL may serve as a gate electrode of the transistor. The switch element TR may also be referred to as an access device or a select device.

The first conductive line BL may extend along a first direction D1. The first direction D1 may be vertical to a top surface of a lower structure LS. The horizontal layer HL may extend along a second direction D2 intersecting the first direction D1. The second direction D2 may be parallel to the top surface of the lower structure LS. The first, second and third directions D1, D2, and D3 may be orthogonal to each other. In some embodiments, the first direction D1 may be a direction vertical to the top surface of the lower structure LS and the second and third directions may be horizontal directions.

The second conductive line DWL may extend along a third direction D3 intersecting the first direction D1 and the second direction D2. The third direction D3 may be parallel to the top surface of the lower structure LS.

In various embodiments, the first conductive line BL may be referred to as a vertically-oriented bit line, a vertically-extended bit line, or a pillar-shaped bit line. The first conductive line BL may be made of any suitable conductive material including, for example, a silicon-base material, a metal-base material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include polysilicon or titanium nitride (TiN) doped with N-type impurities. The first conductive line BL may include a stack (TiN/W) of titanium nitride and tungsten.

The switch element TR may include a transistor, and thus the second conductive line DWL may be referred to as a gate line, or a horizontal gate line or a horizontal word line. In the second conductive line DWL, an upper second conductive line WL1 and a lower second conductive line WL2 may have substantially the same potential. For example, the upper second conductive line WL1 and the lower second conductive line WL2 may form a pair and may be coupled to one memory cell MC. Substantially the same driving voltage may be applied to the upper second conductive line WL1 and the lower second conductive line WL2.

The second conductive line DWL may elongate along the third direction D3 and the horizontal layer HL may extend along the second direction D2. The horizontal layer HL may be laterally arranged from the first conductive line BL. The second conductive line DWL may have a double structure. For example, the second conductive line DWL may include the upper (or top) and lower second conductive lines WL1 and WL2 opposed to each other with the horizontal layer HL interposed therebetween. The gate dielectric layer GD may be formed on an upper surface and a lower surface of the horizontal layer HL. The upper second conductive line WL1 may be disposed above the horizontal layer HL, and the lower second conductive line WL2 may be disposed below the horizontal layer HL. The second conductive line DWL may include a pair of the upper second conductive line WL1 and the lower second conductive line WL2.

The horizontal layer HL may extend along the second direction D2. The horizontal layer HL may be made of a semiconductor material, including, for example, polysilicon, single crystal silicon, germanium, or silicon-germanium. In another embodiment, the horizontal layer HL may include an oxide semiconductor material. Examples of the oxide semiconductor material may include indium gallium zinc oxide (IGZO).

The upper surface and the lower surface of the horizontal layer HL may each have a flat surface. That is, the upper surface and the lower surface of the horizontal layer HL may be parallel to each other along the second direction D2.

The horizontal layer HL may include a channel CH, a first doped region SR between the channel CH and the first conductive line BL, and a second doped region DR between the channel CH and the data storage element CAP. When the horizontal layer HL is an oxide semiconductor material, the channel CH may be made of an oxide semiconductor material, and the first and second doped regions SR and DR may be omitted. The horizontal layer HL may also be referred to as an active layer or a thin-body layer.

The first doped region SR and the second doped region DR may be doped with substantially the same conductivity type of impurities. The first doped region SR and the second doped region DR may be doped with N-type impurities or P-type impurities. The first doped region SR and the second doped region DR may each include at least one impurity selected from arsenic (As), phosphorus (P), boron (B), indium (In), and a combination thereof. The first doped region SR may be coupled to the first conductive line BL, and the second doped region DR may be coupled to the first electrode SN of the data storage element CAP.

The gate dielectric layer GD may include silicon oxide, silicon nitride, metal oxide, metal oxynitride, metal silicate, high-k material, ferroelectric material, anti-ferroelectric material, or a combination thereof. The gate dielectric layer GD may include SiO₂, Si₃N₄, HfO₂, Al₂O₃, ZrO₂, AlON, HfON, HfSiO, HfSiON, or a combination thereof.

The second conductive line DWL may include metal, a metal mixture, a metal alloy, or a semiconductor material. The second conductive line DWL may include titanium nitride, tungsten, molybdenum, ruthenium, polysilicon, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of 4.5 eV or less, and the P-type work function material may have a high work function of 4.5 eV or more.

Each of the upper and lower second conductive lines WL1 and WL2 may include a first electrode G10, a second electrode G20, and a third electrode G30. The first electrode G10 may include a first work function electrode G1 and a first barrier layer G1L, the second electrode G20 may include a second work function electrode G2 and a second barrier layer G2L, and the third electrode G30 may include a third work function electrode G3 and a third barrier layer G3L.

Each of the upper and lower second conductive lines WL1 and WL2 may include the first work function electrode G1, the second work function electrode G2, and the third work function electrode G3. The first work function electrode G1, the second work function electrode G2, and the third work function electrode G3 may be horizontally disposed along the second direction D2. The first work function electrode G1, the second work function electrode G2, and the third work function electrode G3 may be directly contacting one another. The third work function electrode G3 may be adjacent to the first conductive line BL, and the first work function electrode G1 may be adjacent to the data storage element CAP. The second work function electrode G2 may be disposed between the first work function electrode G1 and the third work function electrode G3. The horizontal layer HL may have a thickness smaller than the thicknesses of the first to third work function electrodes G1 to G3.

The first work function electrode G1, the second work function electrode G2, and the third work function electrode G3 may each include titanium nitride, tungsten, molybdenum, ruthenium, polysilicon, or a combination thereof.

The first work function electrode G1, the second work function electrode G2 and the third work function electrode G3 may be made of materials having different work functions. The second work function electrode G2 may have a higher work function than the first and third work function electrodes G1 and G3. The second work function electrode G2 may include a high work function material. The second work function electrode G2 may have a work function higher than the mid-gap work function of silicon. The first and third work function electrodes G1 and G3 may each include a low work function material. The first and third work function electrodes G1 and G3 may each have a lower work function than the mid-gap work function of silicon. Additionally, the high work function material may have a work function higher than 4.5 eV, and the low work function material may have a work function lower than 4.5 eV. The second work function electrode G2 may include a metal-base material, and the first and third work function electrodes G1 and G3 may each include a semiconductor material.

The first and third work function electrodes G1 and G3 may each include an N-type dopant doped polysilicon. The second work function electrode G2 may include metal, metal nitride, or a combination thereof. The second work function electrode G2 may include tungsten, titanium nitride, molybdenum, ruthenium, or a combination thereof. A barrier material may be further formed between the first and third work function electrodes G1 and G3 and the second work function electrode G2.

In the present embodiment, each of the upper and lower second conductive lines WL1 and WL2 of the second conductive line DWL may be horizontally disposed along the second direction D2 in the order of the third work function electrode G3, the second work function electrode G2, and the first work function electrode G1. The second work function electrode G2 may include metal, and the first work function electrode G1 and the third work function electrode G3 may each include polysilicon.

Each of the upper and lower second conductive lines WL1 and WL2 of the second conductive line DWL may have a poly Si-metal-poly Si (PMP) structure disposed along the second direction D2. The second direction D2 may be a horizontal direction. In the PMP structure, the second work function electrode G2 may be a metal-base material, and the first and third work function electrodes G1 and G3 may each be N-type dopant doped polysilicon. The N-type dopant may include phosphorus or arsenic.

The first barrier layer G1L may be disposed an inner space of the first work function electrode G1. The second barrier layer G2L may be disposed between the first work function electrode G1 and the second work function electrode G2. The third barrier layer G3L may be disposed between the second work function electrode G2 and the third work function electrode G3. The first to third barrier layers G1L to G3L may be electrically connected to one another.

The first to third barrier layers G1L to G3L may each include titanium nitride, tantalum nitride, tungsten nitride, or molybdenum nitride. The second barrier layer G2L may surround a part of the second work function electrode G2. The first work function electrode G1 may surround a part of the first barrier layer G1L. The first barrier layer G1L may have a shape of a protrusion that fills an inner surface of the first work function electrode G1.

The first and third work function electrodes G1 and G3 may each have a bent shape or a rectangular cup shape laterally oriented.

Referring to FIGS. 1B and 1C, the first work function electrode G1 may include a plurality of inner surfaces G1A and a plurality of outer surfaces G1B. The inner surfaces G1A of the first work function electrode G1 may cover the first barrier layer G1L and a portion of outer surfaces G1B of the first work function electrode G1 may contact the first electrode SN. Referring to FIGS. 1B and 1D, the third work function electrode G3 may include a plurality of inner surfaces G3A and a plurality of outer surfaces G3B. The inner surfaces G3A of the third work function electrode G3 may cover a gap-fill material GF and portions of the outer surfaces G3B may contact the third barrier layer G3L. The third barrier layer G3L may have a bent shape, a cylindrical shape or a rectangular cup shape laterally oriented covering a part of the outer surface of the third work function electrode G3.

The second work function electrode G2 may have a larger volume than the first and third work function electrodes G1 and G3, and thus the second conductive line DWL may have a low resistance. The first work function electrodes G1 of the upper and lower second conductive lines WL1 and WL2 may vertically overlap along the first direction D1 with the horizontal layer HL interposed therebetween. The second and third work function electrodes G2 and G3 of the upper and lower second conductive lines WL1 and WL2 may vertically overlap along the first direction D1 with the horizontal layer HL interposed therebetween. An overlapping area between the second work function electrode G2 and the horizontal layer HL may be larger than an overlapping area between the first and third work function electrodes G1 and G3 and the horizontal layer HL. The second work function electrode G2 may extend along the third direction D3, and the first and third work function electrodes G1 and G3 may extend from both side surfaces of the second work function electrode G2 along the second direction D2.

As described above, each of the upper and lower second conductive lines WL1 and WL2 may have a triple electrode structure including the first to third work function electrodes G1 to G3. The second conductive line DWL may have a pair of first work function electrodes G1 across the horizontal layer HL with the horizontal layer HL interposed therebetween, a pair of second work function electrodes G2 across the horizontal layer HL with the horizontal layer HL interposed therebetween, and a pair of third work function electrodes G3 across the horizontal layer HL with the horizontal layer HL interposed therebetween. The second work function electrodes G2 of the second conductive line DWL may vertically overlap with the channel CH, the third work function electrodes G3 of the second conductive line DWL may vertically overlap the first doped region SR of the horizontal layer HL, and the first work function electrodes G1 of the second conductive line DWL may vertically overlap the second doped region DR of the horizontal layer HL.

As the second work function electrode G2 having a high work function is disposed at the center of the second conductive line DWL, and the first and third work function electrodes G1 and G3 each having a low work function are disposed at both ends of the second conductive line DWL, leakage current such as gate induced drain leakage (GIDL) can be reduced.

As the second work function electrode G2 having a high work function is disposed at the center of the second conductive line DWL, a threshold voltage of the switch element TR may be increased. Since the third work function electrode G3 of the second conductive line DWL has a low work function, a low electric field may be formed between the first conductive line BL and the second conductive line DWL. Since the first work function electrode G1 of the second conductive line DWL has a low work function, a low electric field may be formed between the data storage element CAP and the second conductive line DWL.

The data storage element CAP may be horizontally disposed along the second direction D2 from the switch element TR. The data storage element CAP may include the first electrode SN extending horizontally from the horizontal layer HL along the second direction D2. The data storage element CAP may further include the second electrode PN on the first electrode SN and the dielectric layer DE between the first electrode SN and the second electrode PN. The first electrode SN, the dielectric layer DE, and the second electrode PN may be laterally arranged along the second direction D2. The first electrode SN may have a horizontally oriented cylinder shape. The dielectric layer DE may conformally cover a cylinder inner wall and a cylinder outer wall of the first electrode SN. The second electrode PN may be disposed on the dielectric layer DE and cover the cylinder inner wall and the cylinder outer wall of the first electrode SN. The first electrode SN may be electrically connected to the second doped region DR.

The first electrode SN may have a three-dimensional structure, and the first electrode SN having the three-dimensional structure may have a horizontal three-dimensional structure oriented along the second direction D2. As an example of the three-dimensional structure, the first electrode SN may have a cylinder shape. In another embodiment, the first electrode SN may have a pillar shape or a pylinder shape. The pylinder shape may refer to a structure in which a pillar shape and a cylinder shape are merged.

The first electrode SN and the second electrode PN may each include metal, noble metal, metal nitride, conductive metal oxide, conductive noble metal oxide, metal carbide, metal silicide, or a combination thereof. For example, the first electrode SN and the second electrode PN may each include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack. The second electrode PN may include a combination of a metal-base material and a silicon-base material. For example, the second electrode PN may be a stack (TiN/SiGe/WN) of titanium nitride/silicon germanium/tungsten nitride. In the titanium nitride/silicon germanium/tungsten nitride (TiN/SiGe/WN) stack, silicon germanium may be a gap-fill material for filling the cylinder inside of the first electrode SN, titanium nitride (TiN) may serve as the second electrode PN of the data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may have a higher dielectric constant than silicon oxide (SiO₂). The silicon oxide (SiO₂) may have a dielectric constant of about 3.9, and the dielectric layer DE may include a high-k material having a dielectric constant of 4 or more. The high-k material may have a dielectric constant of about 20 or greater. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In another embodiment, the dielectric layer DE may also include a composite layer including two or more layers each having the high-k material described above.

The dielectric layer DE may be made of zirconium-base oxide (Zr-base oxide). The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide-base layer (ZrO₂-base layer). In another embodiment, the dielectric layer DE may be made of hafnium-base oxide (Hf-base oxide). The dielectric layer DE may have a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide-base layer (HfO₂-base layer). In the ZA stack, the ZAZ stack, the HA stack, and the HAH stack, aluminum oxide (Al₂O₃) may have higher bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high bandgap material having higher bandgap energy than the high-k material. The dielectric layer DE may also include silicon oxide (SiO₂) as another high bandgap material in addition to aluminum oxide (Al₂O₃). Since the dielectric layer DE includes a high bandgap material, leakage current may be suppressed. The high bandgap material may be thinner than the high-k material. In another embodiment, the dielectric layer DE may include a laminated structure in which a high-k material and a high bandgap material are alternately stacked. For example, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HAHA (HfO₂/Al₂O₃/HfO₂/Al₂O₃) stack, or an HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

In another embodiment, the dielectric layer DE may include a stack structure, a laminated structure, or a mutual mixing structure including zirconium oxide, hafnium oxide, and aluminum oxide.

In another embodiment, an interface control layer for reducing leakage current may be further formed between the first electrode SN and the dielectric layer DE. The interface control layer may include titanium oxide (TiO₂), tantalum oxide (Ta₂O₅), or niobium oxide (Nb₂O₅). The interface control layer may also be formed between the second electrode PN and the dielectric layer DE.

The data storage element CAP may include a metal-insulator-metal (MIM) capacitor. The first electrode SN and the second electrode PN may each include a metal-base material.

The data storage element CAP may also be replaced with another data storage material. For example, the data storage material may be a phase change material, a magnetic tunnel junction (MTJ), or a variable resistance material.

The second conductive line DWL and the horizontal layer HL may be disposed between cell insulating layers IL. The cell insulating layers IL may each include an insulating material.

A first contact node may be formed between the first doped region SR and the first conductive line BL. The first contact node may include N-type dopant doped polysilicon. The first doped region SR may include dopants diffused from the first contact node. In another embodiment, an ohmic contact may be formed between the first contact node and the first conductive line BL. The ohmic contact may include metal silicide.

In another embodiment, a second contact node may be formed between the second doped region DR and the first electrode SN of the data storage element CAP. The second contact node may include N-type dopant doped polysilicon. The second doped region DR may include dopants diffused from an additional contact node.

A first capping layer BC may be disposed between the first conductive line BL and the third work function electrode G3. A second capping layer CC may be disposed between the first work function electrode G1 and the first electrode SN. The first and second capping layers BC and CC may each include an insulating material. The first and second capping layers BC and CC may each include silicon oxide, silicon nitride, SiCN, SiCO, SiCON, or a combination thereof.

As described above, the memory cell MC may include the second conductive line DWL having a triple work function electrode structure. Each of the upper and lower second conductive lines WL1 and WL2 of the second conductive line DWL may include the first work function electrode G1, the second work function electrode G2, and the third work function electrode G3. The second work function electrode G2 may overlap with the channel CH, the third work function electrode G3 may be adjacent to the first conductive line BL and the first doped region SR, and the first work function electrode G1 may be adjacent to the data storage element CAP and the second doped region DR. Due to the low work function of the third work function electrode G3, a low electric field may be formed between the second conductive line DWL and the first conductive line BL, thereby making it possible to reduce leakage current. Due to the low work function of the first work function electrode G1, a low electric field may be formed between the second conductive line DWL and the data storage element CAP, thereby making it possible to reduce leakage current. Due to the high work function of the second work function electrode G2, a high threshold voltage of the switch element TR may be formed, and the height of the memory cell MC may be reduced due to the formation of a low electric field, which is advantageous in terms of integration.

As comparative example 1, when each upper and lower second conductive lines WL1 and WL2 is made of only a metal-base material, a high electric field is formed between the upper and lower second conductive lines WL1 and WL2 and the data storage element CAP due to a high work function of the metal-base material, which increases the leakage current of the memory cell MC. Such an increase in leakage current due to the high electric field intensifies as the channel CH becomes thinner.

As comparative example 2, when each of the upper and lower second conductive lines WL1 and WL2 is made of only a low work function material, the threshold voltage of the switch element TR decreases due to the low work function, resulting in the generation of leakage current.

In the present embodiment, since the upper and lower second conductive lines WL1 and WL2 of the second conductive line DWL each have a triple electrode structure, leakage current can be reduced and thus the refresh characteristics of the memory cell MC can be secured, which makes it possible to achieve low power consumption.

Furthermore, in the present embodiment, the first and lower second conductive lines WL1 and WL2 of the second conductive line DWL may each have a triple electrode structure, which is relatively advantageous in an increase in an electric field even though the thickness of the channel CH is reduced for high integration, thereby making it possible to implement a high number of stacked layers.

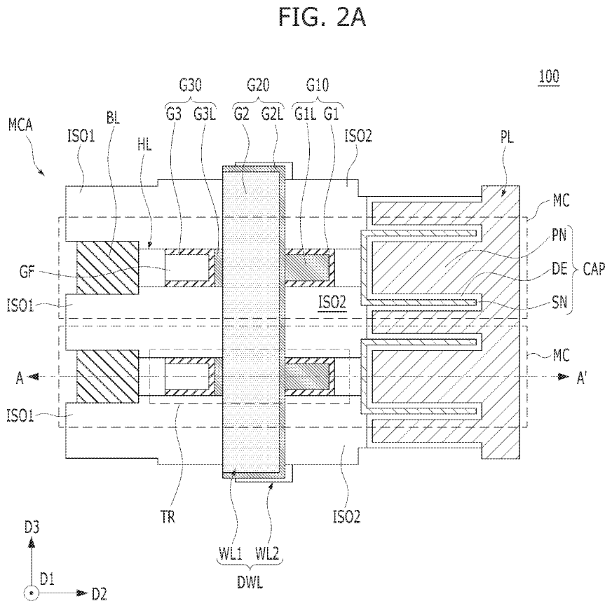

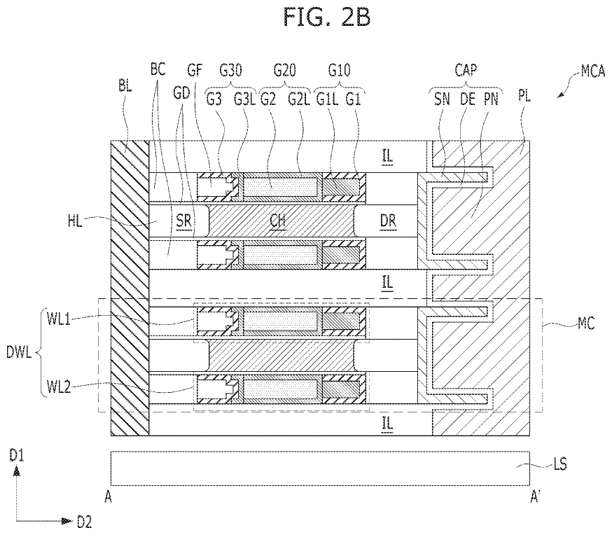

FIG. 2A is a simplified schematic plan view of a semiconductor device 100 in accordance with an embodiment. FIG. 2B is a cross-sectional view taken along line A-A′ in FIG. 2A. Hereinafter, a detailed description of the overlapping components will refer to FIG. 1A and FIG. 1B.

Referring to FIG. 2A and FIG. 2B, the semiconductor device 100 may include a lower structure LS and a memory cell array MCA. The memory cell array MCA may include a three-dimensional array of memory cells MC. The three-dimensional array of the memory cells MC may include a column array of the memory cells MC and a row array of the memory cells MC. In the column array of the memory cells MC, a plurality of memory cells MC may be stacked along a first direction D1, and in the row array of memory cells MC, a plurality of memory cells MC may be horizontally disposed along a third direction D3. In some embodiments, cell insulating layers IL may be disposed between the memory cells MC stacked along the first direction D1. Isolation layers ISO1 and ISO2 may be disposed between the memory cells MC along the third direction D3. The isolation layers ISO1 and ISO2 may include first isolation layers ISO1 and second isolation layers ISO2. The first isolation layers ISO1 may be disposed between first conductive lines BL along the third direction D3, and the second isolation layers ISO2 may be disposed between second conductive lines DWL and data storage elements CAP along a second direction D2.

The individual memory cell MC may include the first conductive line BL, a switch element TR, and the data storage element CAP. The individual switch element TR is a transistor and may include a horizontal layer HL, a gate dielectric layer GD, and a second conductive line DWL. The individual horizontal layer HL may include a first doped region SR, a second doped region DR, and a channel CH between the first doped region SR and the second doped region DR. The individual second conductive line DWL may include a pair of an upper second conductive line WL1 and a lower second conductive line WL2. The individual upper second conductive line WL1 and the individual lower second conductive line WL2 may each include a first work function electrode G1, a second work function electrode G2, and a third work function electrode G3. The individual data storage element CAP may include a first electrode SN, a second electrode PN, and a dielectric layer DE between the first electrode SN and the second electrode PN.

The column array of the memory cells MC may include a plurality of switch elements TR stacked along the first direction D1, and the row array of the memory cells MC may include a plurality of switch elements TR horizontally disposed along the third direction D3.

The horizontal layers HL may be stacked on the lower structure LS along the first direction D1, and may be spaced apart from the lower structure LS to extend along the second direction D2 parallel to the surface of the lower structure LS.

The first conductive line BL may extend along the first direction D1 perpendicular to the surface of the lower structure LS and may be coupled to one ends of the horizontal layers HL.

The data storage elements CAP may be coupled to the other ends of the horizontal layers HL, respectively.

The second conductive lines DWL may be stacked above the lower structure LS along the first direction D1, and may also be spaced apart from the lower structure LS to extend along the third direction D3 parallel to the surface of the lower structure LS.

Second electrodes PN of the data storage elements CAP may be coupled to a common plate PL. The horizontal layers HL of the switch elements TR horizontally disposed along the third direction D3 may share one second conductive line DWL. The horizontal layers HL of the switch elements TR horizontally disposed along the third direction D3 may be coupled to different first conductive lines BL. The switch elements TR stacked along the first direction D1 may share one first conductive line BL. The switch elements TR horizontally disposed along the third direction D3 may share one second conductive line DWL.

The lower structure LS may include a semiconductor substrate or a peripheral circuit unit. The lower structure LS may be disposed at a lower level than the memory cell array MCA. This may be referred to as a cell over PERI (COP) structure. The peripheral circuit unit may include at least one control circuit for driving the memory cell array MCA. The at least one control circuit of the peripheral circuit unit may include an N-channel transistor, a P-channel transistor, a CMOS circuit, or a combination thereof. The at least one control circuit of the peripheral circuit unit may include an address decoder circuit, a read circuit, a write circuit, and the like. The at least one control circuit of the peripheral circuit unit may include a planar channel transistor, a recess channel transistor, a buried gate transistor, a fin channel transistor (FinFET), and the like.

For example, the peripheral circuit unit may include sub-word line drivers and a sense amplifier. The second conductive lines DWL may be coupled to the sub-word line drivers. The first conductive line BL may be coupled to the sense amplifier.

In another embodiment, the peripheral circuit unit may be disposed at a higher level than the memory cell array MCA. This may be referred to as a PERI over cell (POC) structure.

The memory cell array MCA may include second conductive lines DWL stacked along the first direction D1. The individual second conductive lines DWL may each include a pair of an upper second conductive line WL1 and a lower second conductive line WL2.

Each of the upper and lower second conductive lines WL1 and WL2 may include a first work function electrode G1, a second work function electrode G2, and a third work function electrode G3. The first work function electrode G1, the second work function electrode G2, and the third work function electrode G3 may be horizontally disposed along the second direction D2.

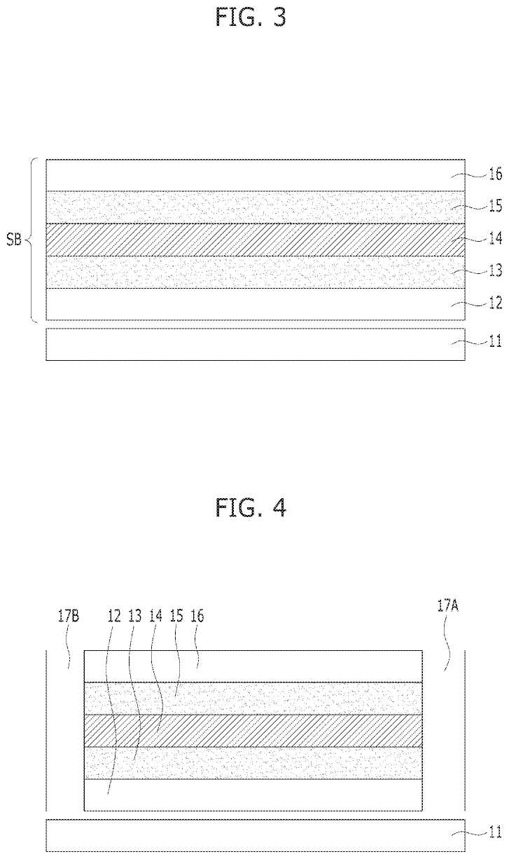

FIG. 3 to FIG. 21 are views for explaining an example of a method for fabricating a semiconductor device in accordance with an embodiment.

As illustrated in FIG. 3, a stack body SB may be formed on a lower structure 11. In the stack body SB, a plurality of sub-stacks may be alternately stacked. The individual sub-stack may be stacked in the order of a first insulating layer 12, a first sacrificial layer 13, a semiconductor layer 14, a second sacrificial layer 15, and a second insulating layer 16. The first and second insulating layers 12 and 16 may each include silicon oxide, and the first and second sacrificial layers 13 and 15 may each include silicon nitride. The semiconductor layer 14 may include a semiconductor material or an oxide semiconductor material. The semiconductor layer 14 may include single crystal silicon, polysilicon, or indium gallium zinc oxide (IGZO). As described in the embodiments described above, when memory cells are stacked, the stack body SB may be stacked several times.

As illustrated in FIG. 4, a part of the stack body SB may be etched to form first and second openings 17A and 17B. The first and second openings 17A and 17B may extend vertically from the surface of the lower structure 11. Before the first and second openings 17A and 17B are formed, the stack body SB may be patterned in units of memory cells as referred to in FIG. 2A and FIG. 2B.

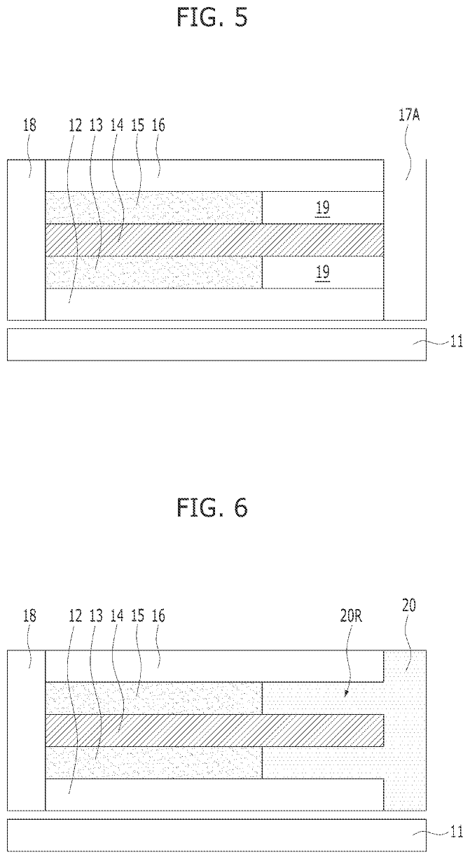

As illustrated in FIG. 5, a first sacrificial gap-fill layer 18 filling the second opening 17B may be formed. The first sacrificial gap-fill layer 18 may include an insulating material.

Subsequently, in the first opening 17A, the first and second sacrificial layers 13 and 15 may be selectively etched to form recesses 19. A part of the semiconductor layer 14 may be exposed by the recesses 19. The recesses 19 may be disposed between the first and second insulating layers 12 and 16 and the semiconductor layer 14.

As illustrated in FIG. 6, a second sacrificial gap-fill layer 20 filling the recesses 19 and the first opening 17A may be formed. The second sacrificial gap-fill layer 20 may include an insulating material. The second sacrificial gap-fill layer 20 may include expansion portions 20R filling the recesses 19, respectively.

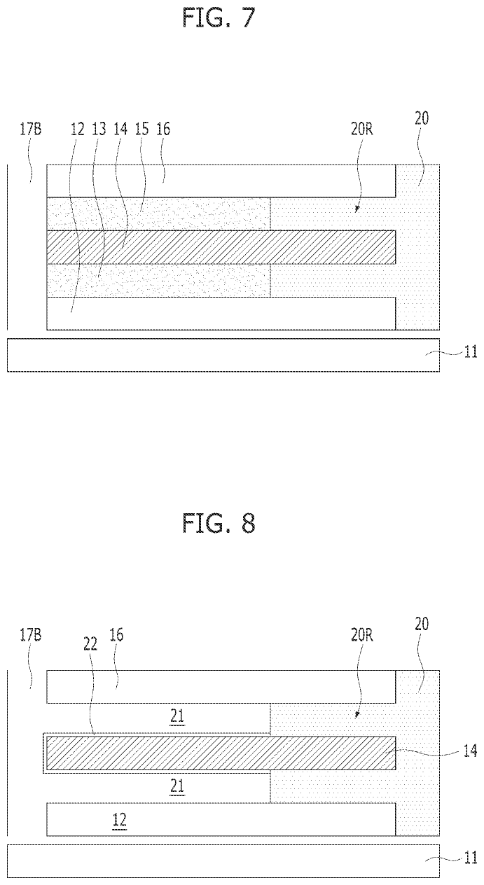

As illustrated in FIG. 7, the first sacrificial gap-fill layer 18 may be removed to expose the second opening 17B again.

As illustrated in FIG. 8, the first and second sacrificial layers 13 and 15 may be removed through the second opening 17B. Accordingly, horizontal recesses 21 exposing parts of the semiconductor layer 14 may be formed. The horizontal recesses 21 may be disposed between the first and second insulating layers 12 and 16 and the semiconductor layer 14. The horizontal recesses 21 may be referred to as word line-level recesses or gate-level recesses.

Subsequently, a gate dielectric layer 22 may be formed on the exposed portion of the semiconductor layer 14. The gate dielectric layer 22 may include silicon oxide, silicon nitride, metal oxide, metal oxynitride, metal silicate, high-k material, ferroelectric material, antiferroelectric material, or a combination thereof. The gate dielectric layer 22 may include SiO₂, Si₃N₄, HfO₂, Al₂O₃, ZrO₂, AlON, HfON, HfSiO, HfSiON, or the like.

In the present embodiment, the gate dielectric layer 22 may be formed by an oxidation process, and a part of the semiconductor layer 14 may be thinned. A thin portion of the semiconductor layer 14 may be referred to as a thin body.

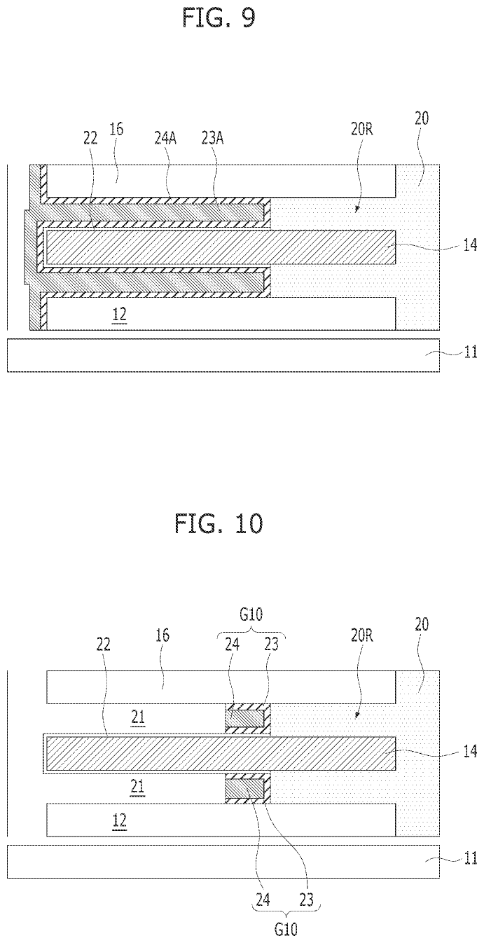

As illustrated in FIG. 9, a first work function material 23A and a first barrier material 24A may be sequentially formed in the horizontal recesses 21.

The first work function material 23A may be conformally formed, and conformally cover the horizontal recesses 21 on the gate dielectric layer 22. The first work function material 23A may be made of a conductive material. The first work function material 23A may have a work function lower than the mid-gap work function of silicon. For example, the first work function material 23A may include N-type dopant doped polysilicon. The N-type dopant may include phosphorus (P) or arsenic (As).

The first barrier material 24A may include a metal-base material. The first barrier material 24A may include metal nitride. The first barrier material 24A may include titanium nitride.

As illustrated in FIG. 10, a first electrode G10 may be formed. The first electrode G10 may include a first work function electrode 23 and a first barrier layer 24. In order to form the first work function electrode 23 and the first barrier layer 24, the first work function material 23A and the first barrier material 24A may be selectively recessed.

A pair of first low work function electrodes 23 may be formed with the semiconductor layer 14 interposed therebetween. The first work function electrode 23 may have a bent shape or a rectangular cup shape laterally oriented. The first work function electrode 23 may partially surround the first barrier layer 24.

Insides of the horizontal recesses 21 may be filled with first electrodes G10.

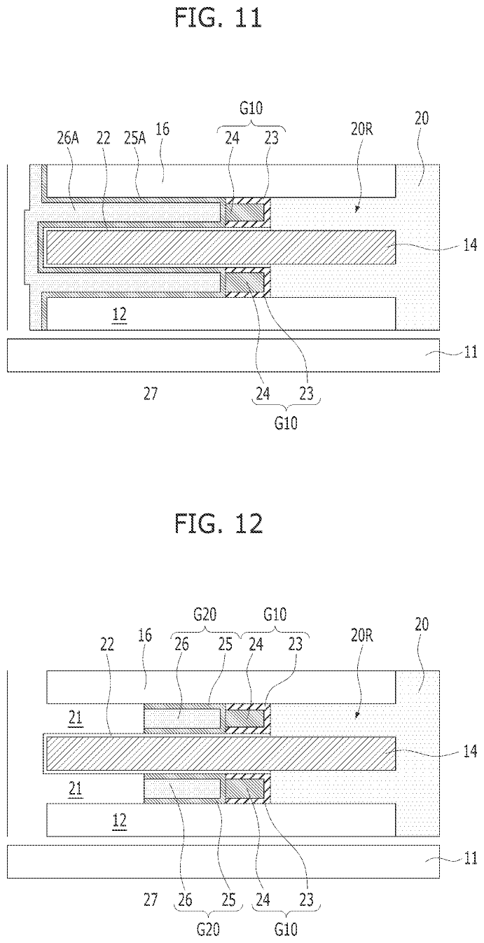

As illustrated in FIG. 11, a second barrier material 25A and a second work function material 26A may be sequentially formed on the first electrode G10 to gap-fill the remaining portions of the horizontal recesses 21. The second barrier material 25A may include a metal-base material. The second barrier material 25A may include metal nitride. The second work function material 26A may have a work function higher than the mid-gap work function of silicon. The second work function material 26A may have a higher work function than the first work function electrode 23. The second work function material 26A may have lower resistance than the first work function electrode 23. The second work function material 26A may include a metal-base material. The second work function material 26A may include metal nitride, metal, or a combination thereof. The second work function material 26A may include titanium nitride, tungsten, or a combination thereof. In the stack of the second barrier material 25A and the second work function material 26A, titanium nitride and tungsten may be sequentially stacked.

As illustrated in FIG. 12, a second electrode G20 may be formed in the horizontal recesses 21. The second electrode G20 may include a second barrier layer 25 and a second work function electrode 26. In order to form the second barrier layer 25 and the second work function electrode 26, the second barrier material 25A and the second work function material 26A may be selectively etched.

The second work function electrode 26 may be adjacent to one side surface of the first work function electrode 23 with the second barrier layer 25 interposed therebetween. The second work function electrode 26 may have a higher work function than the first work function electrode 23. The second work function electrode 26 may include a metal-base material. For example, the second work function electrode 26 may include titanium nitride, tungsten, or a combination thereof.

A pair of second work function electrodes 26 may be formed with the semiconductor layer 14 therebetween.

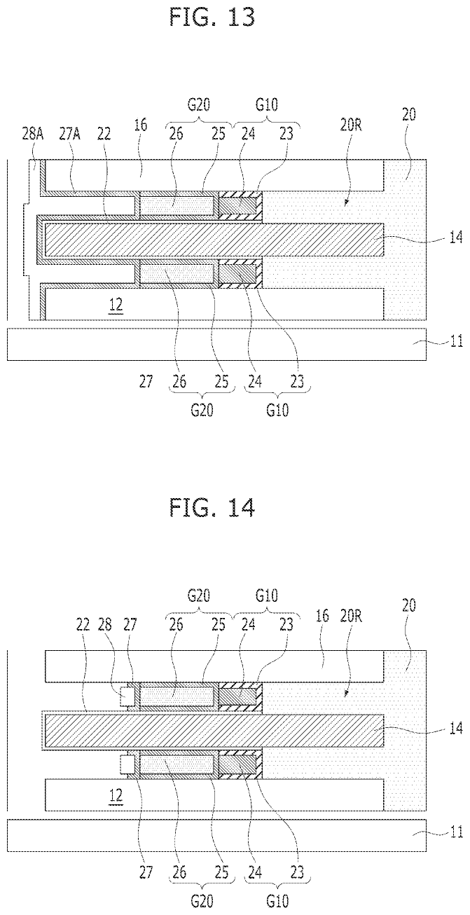

As illustrated in FIG. 13, a third barrier material 27A and a first sacrificial barrier material 28A may be sequentially formed on the second electrode G20. The third barrier material 27A may include a metal-base material. The third barrier material 27A may include metal nitride. The third barrier material 27A may include titanium nitride. The first sacrificial barrier material 28A may include polysilicon.

As illustrated in FIG. 14, to form a first sacrificial barrier 28, the sacrificial barrier material 28A may be selectively recessed.

Subsequently, the third barrier material 27A may be selectively etched using the first sacrificial barrier 28 as an etch stopper. Accordingly, a third barrier layer 27 contacting the second work function electrode 26 and the second barrier layer 25 may be formed.

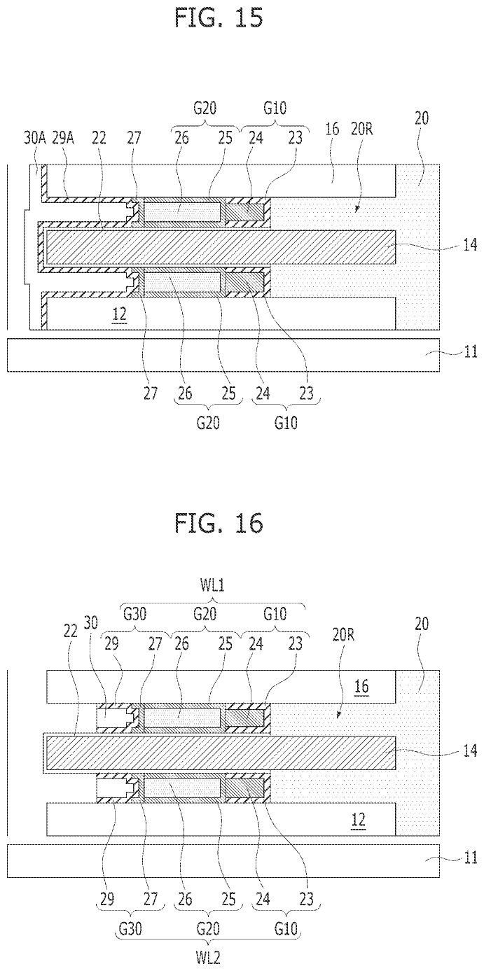

As illustrated in FIG. 15, after the first sacrificial barrier 28 is removed, a third work function material 29A may be formed on the third barrier layer 27. The third work function material 29A may be made of a conductive material. The third work function material 29A may have a work function lower than the mid-gap work function of silicon. For example, the third work function material 29A may include N-type dopant doped polysilicon. The N-type dopant may include phosphorus (P) or arsenic (As).

A gap-fill material layer 30A may be formed on the third work function material 29A. The gap-fill material layer 30A may include silicon oxide.

As illustrated in FIG. 16, to form a third work function electrode 29 and a gap-fill material 30, the third work function material 29A and the gap-fill material layer 30A may be selectively etched. The third work function electrode 29 may have a bent shape or a rectangular cup shape laterally oriented. The third work function electrode 29 may surround parts of the gap-fill material 30.

The third barrier layer 27 and the third work function electrode 29 may constitute a third electrode G30.

Through a series of processes described above, an upper second conductive line WL1 and a lower second conductive line WL2 vertically opposed to each other with the semiconductor layer 14 interposed therebetween may be formed. The upper second conductive line WL1 and the lower second conductive line WL2 may form a pair to constitute a double structure second conductive line also referred to as dual structure conductive line.

In the dual structure conductive line, a pair of first electrodes G10, a pair of second electrodes G20, and a pair of third electrodes G30 may be formed. The first electrode G10 may include the first work function electrode 23 and the first barrier layer 24. The second electrode G20 may include the second work function electrode 26 and the second barrier layer 25. The third electrode G30 may include the third work function electrode 29 and the third barrier layer 27.

Furthermore, a pair of first work function electrodes 23 may be formed with the semiconductor layer 14 interposed therebetween, a pair of second work function electrodes 26 may be formed with the semiconductor layer 14 interposed therebetween, and a pair of third work function electrodes 29 may be formed with the semiconductor layer 14 interposed therebetween.

Mutual diffusion between the first work function electrode 23 and the second work function electrode 26 may be substantially prevented by the first and second barrier layers 24 and 25. Mutual diffusion between the second work function electrode 26 and the third work function electrode 29 may be substantially prevented by the third barrier layer 27.

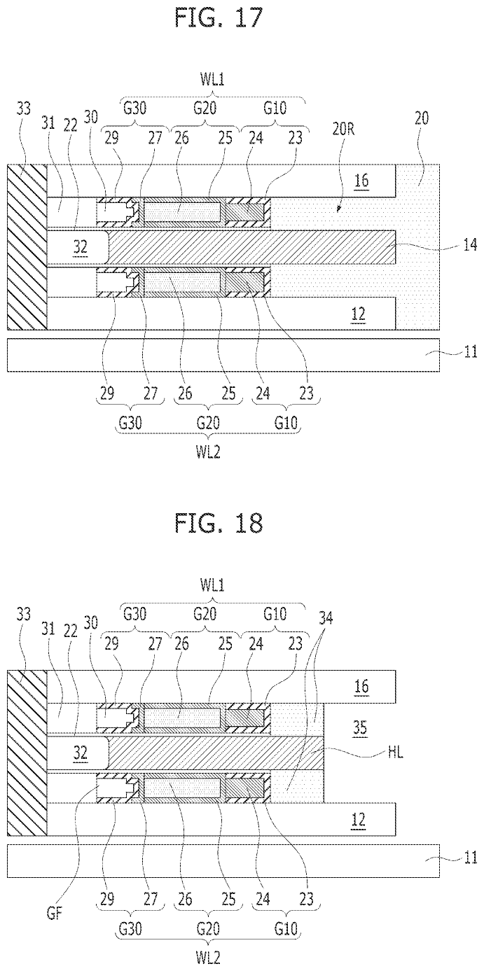

As illustrated in FIG. 17, a first capping layer 31 may be formed. The first capping layer 31 may include an insulating material. The first capping layer 31 may include silicon oxide, silicon nitride, SiCN, SiCO, SiCON, or a combination thereof.

Subsequently, a first conductive line 33 coupled to the horizontal layer 14 may be formed. The first conductive line 33 may include titanium nitride, tungsten, or a combination thereof. The first conductive line 33 may be a bit line.

Before the first conductive line 33 is formed, a first doped region 32 may be formed at one end of the semiconductor layer 14. The first doped region 32 may be formed by a doping process of impurities.

As illustrated in FIG. 18, after the second sacrificial gap-fill layer 20 is removed, the first and second sacrificial layers 13 and 15 may be selectively recessed. Accordingly, second capping layers 34 may be formed on side surfaces of the first work function electrode 23, respectively.

After the recess process of the first and second sacrificial layers 13 and 15, the other side of the semiconductor layer 14 may be cut to form the horizontal layer HL.

After the second capping layers 34 and the horizontal layer HL are formed, a storage opening 35 or a capacitor opening may be defined between the insulating layers 12 and 16.

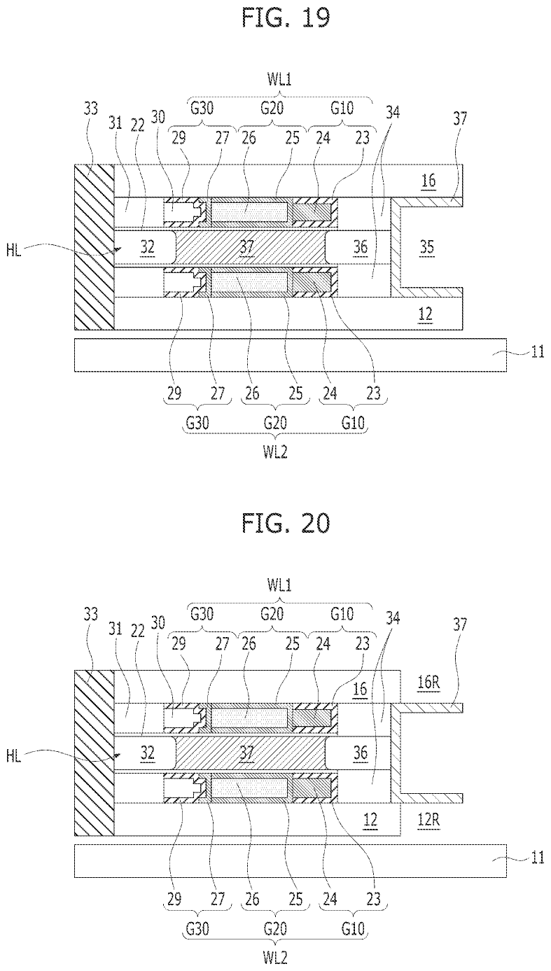

As illustrated in FIG. 19, a second doped region 36 may be formed at the other ends of the horizontal layers HL. The second doped region 36 may be formed by a doping process of impurities.

Subsequently, a first electrode 37 of a data storage element respectively contacting the second doped regions 36 may be formed. In order to form the first electrode 37, conductive material deposition and etch-back process may be performed. The first electrode 37 may include titanium nitride. The first electrode 37 may have a horizontally oriented cylindrical shape. The first electrode 37 may be formed in the storage opening 35.

As illustrated in FIG. 20, the insulating layers 12 and 16 may be partially recessed (12R and 16R). Accordingly, outer walls of the first electrodes 37 may be exposed. The remaining insulating layers 12 and 16 may be referred to as cell isolation layers.

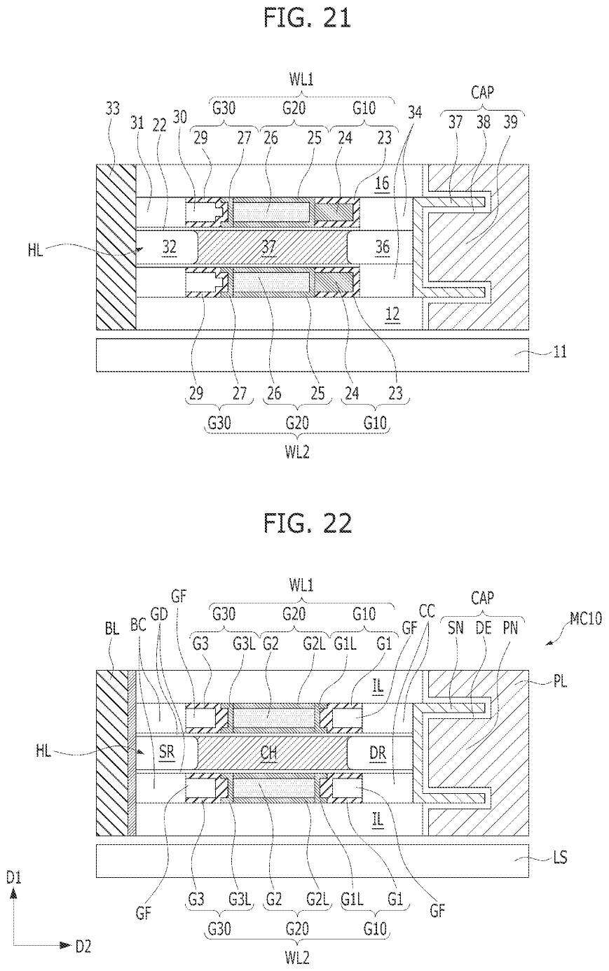

As illustrated in FIG. 21, a dielectric layer 38 and a second electrode 39 may be sequentially formed on the first electrodes 37. The first electrode 37, the dielectric layer 38, and the second electrode 39 may constitute a data storage element (CAP).

FIG. 22 is a simplified schematic cross-sectional view of a memory cell MC10 in accordance with another embodiment. The memory cell MC10 of FIG. 22 may be similar to the memory cell MC of FIG. 1B. Hereinafter, a detailed description of the overlapping components will refer to FIG. 1A and FIG. 1B.

Referring to FIG. 22, the memory cell MC10 may include a first conductive line BL, a switch element TR, and a data storage element CAP. The switch element TR may include a horizontal layer HL, a gate dielectric layer GD, and a second conductive line DWL. The data storage element CAP may be a memory element such as a capacitor. The first conductive line BL may be a bit line. The second conductive line DWL may be a word line, and the horizontal layer HL may be an active layer. The data storage element CAP may include a first electrode SN, a second electrode, and a dielectric layer DE positioned between the first and second electrodes SN, PN. The switch element TR may include a transistor, and in this case, the second conductive line DWL may serve as a gate electrode. The switch element TR may also be referred to as an access element or a selection element.

The first conductive line BL may vertically extend along a first direction D1. The horizontal layer HL may extend along a second direction D2 intersecting the first direction D1. The second conductive line DWL may extend along a third direction D3 intersecting the first direction D1 and the second direction D2.

The second conductive line DWL may elongate along the third direction D3 and the horizontal layer HL may extend along the second direction D2. The horizontal layer HL may be laterally arranged from the first conductive line BL. The second conductive line DWL may have a double structure. For example, the second conductive line DWL may include first and lower second conductive lines WL1 and WL2 opposed to each other with the horizontal layer HL interposed therebetween. The gate dielectric layer GD may be formed on an upper surface and a lower surface of the horizontal layer HL. The upper second conductive line WL1 may be disposed above the horizontal layer HL, and the lower second conductive line WL2 may be disposed below the horizontal layer HL. The second conductive line DWL may include a pair of the upper second conductive line WL1 and the lower second conductive line WL2.

The horizontal layer HL may extend along the second direction D2. The horizontal layer HL may include a semiconductor material. For example, the horizontal layer HL may include polysilicon, single crystal silicon, germanium, or silicon-germanium. In another embodiment, the horizontal layer HL may include an oxide semiconductor material. For example, the oxide semiconductor material may include indium gallium zinc oxide (IGZO).

The upper surface and the lower surface of the horizontal layer HL may each have a flat surface. That is, the upper surface and the lower surface of the horizontal layer HL may be parallel to each other along the second direction D2.

The horizontal layer HL may include a channel CH, a first doped region SR between the channel CH and the first conductive line BL, and a second doped region DR between the channel CH and the data storage element CAP. The first doped region SR may be coupled to the first conductive line BL, and the second doped region DR may be coupled to the first electrode SN of the data storage element CAP.

Each of the upper and lower second conductive lines WL1 and WL2 may include a first electrode G10, a second electrode G20, and a third electrode G30. The first electrode G10 may include a first work function electrode G1 and a first barrier layer G1L, the second electrode G20 may include a second work function electrode G2 and a second barrier layer G2L, and the third electrode G30 may include a third work function electrode G3 and a third barrier layer G3L.

Each of the upper and lower second conductive lines WL1 and WL2 may include the first work function electrode G1, the second work function electrode G2, and the third work function electrode G3. The first work function electrode G1, the second work function electrode G2, and the third work function electrode G3 may be horizontally disposed along the second direction D2. The first work function electrode G1, the second work function electrode G2, and the third work function electrode G3 may be parallel to one another while directly contacting one another. The third work function electrode G3 may be adjacent to the first conductive line BL, and the first work function electrode G1 may be adjacent to the data storage element CAP. The second work function electrode G2 may be disposed between the first work function electrode G1 and the third work function electrode G3. The horizontal layer HL may have a thickness smaller than those of the first to third work function electrodes G1 to G3.

The first work function electrode G1, the second work function electrode G2, and the third work function electrode G3 may each include titanium nitride, tungsten, molybdenum, ruthenium, polysilicon, or a combination thereof.

The first work function electrode G1, the second work function electrode G2, and the third work function electrodes G3 are made of materials having different work functions. The second work function electrode G2 may have a higher work function than the first and third work function electrodes G1 and G3. The second work function electrode G2 may include a high work function material. The second work function electrode G2 may have a work function higher than the mid-gap work function of silicon. The first and third work function electrodes G1 and G3 may each include a low work function material. The first and third work function electrodes G1 and G3 may each have a work function lower than the mid-gap work function of silicon. Additionally, the high work function material may have a work function higher than 4.5 eV, and the low work function material may have a work function lower than 4.5 eV. The second work function electrode G2 may include a metal-base material, and the first and third work function electrodes G1 and G3 may each include a semiconductor material.

The first and third work function electrodes G1 and G3 may each include N-type dopant doped polysilicon. The second work function electrode G2 may include metal, metal nitride, or a combination thereof. The second work function electrode G2 may include tungsten, titanium nitride, molybdenum, ruthenium, or a combination thereof. A barrier material may be further formed between the first and third work function electrodes G1 and G3 and the second work function electrode G2.

In the present embodiment, each of the upper and lower second conductive lines WL1 and WL2 of the second conductive line DWL may be horizontally disposed along the second direction D2 in the order of the third work function electrode G3, the second work function electrode G2, and the first work function electrode G1. The second work function electrode G2 may include metal, and the first work function electrode G1 and the third work function electrode G3 may each include polysilicon.

Each of the upper and lower second conductive lines WL1 and WL2 of the second conductive line DWL may have a poly Si-metal-poly Si (PMP) structure horizontally disposed along the second direction D2. In the PMP structure, the second work function electrode G2 may be a metal-base material, and the first and third work function electrodes G1 and G3 may each be N-type dopant doped polysilicon. The N-type dopant may include phosphorus or arsenic.

The first barrier layer G1L may be disposed between the first work function electrode G1 and the second work function electrode G2. The second barrier layer G2L may be disposed on each of an upper surface and a lower surface of the second work function electrode G2. The third barrier layer G3L may be disposed between the second work function electrode G2 and the third work function electrode G3. The first to third barrier layers G1L to G3L may be electrically connected to one another.

The first to third barrier layers G1L to G3L may each include titanium nitride, tantalum nitride, tungsten nitride, or molybdenum nitride.

The first barrier layer G1L may have a bent shape or a rectangular cup shape laterally oriented covering a part of an outer surface of the first work function electrode G1. The third barrier layer G3L may have a bent shape or a rectangular cup shape laterally oriented covering a part of an outer surface of the third work function electrode G3.

The first and third work function electrodes G1 and G3 may each have a bent shape, a cylindrical shape or a rectangular cup shape laterally oriented. The first work function electrode G1 and the third work function electrode G3 may be symmetrical to each other with respect to the second work function electrode G2.

The first work function electrode G1 may include an inner surface covering a gap-fill material GF and the outer surface contacting the first barrier layer G1L. The first barrier layer G1L may have a bent shape, a cylindrical shape or a rectangular cup shape laterally oriented covering a part of the outer surface of the first work function electrode G3.

The third work function electrode G3 may include an inner surface covering the gap-fill material GF and the outer surface contacting the third barrier layer G3L. The third barrier layer G3L may have a bent shape, a cylindrical shape or a rectangular cup shape laterally oriented covering a part of the outer surface of the third work function electrode G3.

As described above, each of the upper and lower second conductive lines WL1 and WL2 may have a triple electrode structure including the first to third work function electrodes G1 to G3. The second conductive line DWL may have a pair of first work function electrodes G1 across the horizontal layer HL with the horizontal layer HL interposed therebetween, a pair of second work function electrodes G2 across the horizontal layer HL with the horizontal layer HL interposed therebetween, and a pair of third work function electrodes G3 across the horizontal layer HL with the horizontal layer HL interposed therebetween. The second work function electrodes G2 of the second conductive line DWL may vertically overlap with the channel CH, the third work function electrodes G3 of the second conductive line DWL may vertically overlap the first doped region SR of the horizontal layer HL, and the first work function electrodes G1 of the second conductive line DWL vertically overlap the second doped region DR of the horizontal layer HL.

As the second work function electrode G2 having a high work function is disposed at the center of the second conductive line DWL, and the first and third work function electrodes G1 and G3 each having a low work function are disposed at both ends of the second conductive line DWL, leakage current such as gate induced drain leakage (GIDL) can be reduced.

As the second work function electrode G2 having a high work function is disposed at the center of the second conductive line DWL, a threshold voltage of the switch element TR may be increased. Since the third work function electrode G3 of the second conductive line DWL has a low work function, a low electric field may be formed between the first conductive line BL and the second conductive line DWL. Since the first work function electrode G1 of the second conductive line DWL has a low work function, a low electric field may be formed between the data storage element CAP and the second conductive line DWL.

As described above, the memory cell MC10 may include the second conductive line DWL having a triple work function electrode structure. Each of the upper and lower second conductive lines WL1 and WL2 of the second conductive line DWL may include the first work function electrode G1, the second work function electrode G2, and the third work function electrode G3. The second work function electrode G2 may overlap with the channel CH, the third work function electrode G3 may be adjacent to the first conductive line BL and the first doped region SR, and the first work function electrode G1 may be adjacent to the data storage element CAP and the second doped region DR. Due to the low work function of the third work function electrode G3, a low electric field may be formed between the second conductive line DWL and the first conductive line BL, thereby making it possible to reduce leakage current. Due to the low work function of the first work function electrode G1, a low electric field may be formed between the second conductive line DWL and the data storage element CAP, thereby making it possible to reduce leakage current. Due to the high work function of the second work function electrode G2, a high threshold voltage of the switch element TR may be formed, and the height of the memory cell MC may be reduced due to the formation of a low electric field, which is advantageous in terms of integration.

In the present embodiment, the first and lower second conductive lines WL1 and WL2 of the second conductive line DWL make each have a triple electrode structure, which makes it possible to reduce leakage current and thus to secure the refresh characteristics of the memory cell MC10 to achieve low power consumption.

Furthermore, in the present embodiment, the upper and lower second conductive lines WL1 and WL2 of the second conductive line DWL may each have a triple electrode structure, which is relatively advantageous in an increase in an electric field even though the thickness of the channel CH is reduced for high integration, thereby making it possible to implement a high number of stacked layers.

FIG. 23 to FIG. 40 are views for explaining an example of a method for fabricating a semiconductor device in accordance with other embodiments.

As illustrated in FIG. 23, a stack body EP may be formed on a lower structure 11. In the stack body EP, a plurality of sub-stacks may be alternately stacked. The individual sub-stack may be stacked in the order of a sacrificial layer 41, a sacrificial semiconductor layer 42, a semiconductor layer 43, a sacrificial semiconductor layer 42, and the sacrificial layer 41. The sacrificial layers 41 may each include silicon germanium, and the sacrificial semiconductor layers 42 may each include single crystal silicon. The semiconductor layer 43 may include single crystal silicon. The sacrificial layers 41, the sacrificial semiconductor layers 42, and the semiconductor layer 43 may be formed by epitaxial growth. The sacrificial layers 41 may be thinner than the sacrificial semiconductor layers 42, and the semiconductor layer 43 may be thicker than the sacrificial semiconductor layers 42.

A hard mask layer 44 may be formed on the stack body EP.

As described in the embodiments described above, when memory cells are stacked, the stack body EP may be stacked several times.

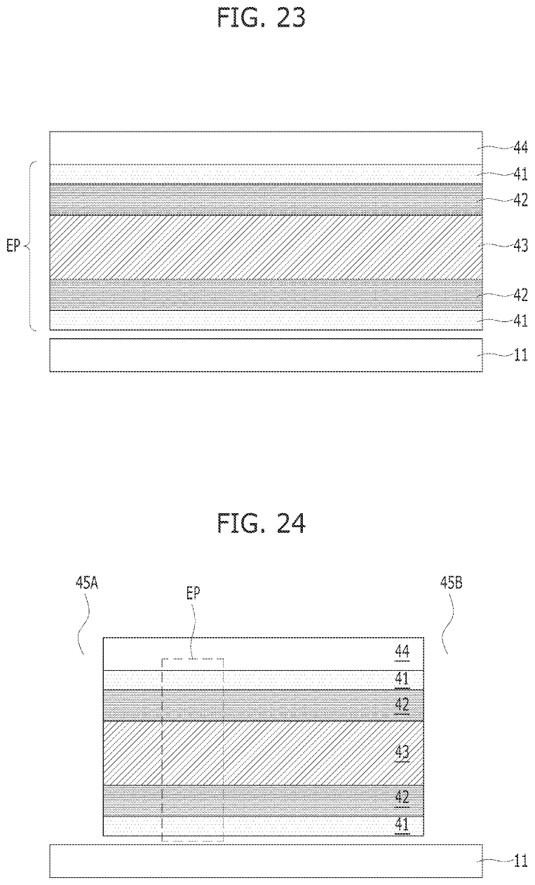

As illustrated in FIG. 24, a first opening 45A and a second opening 45B may be formed by etching a part of the stack body EP. The first and second openings 45A and 45B may extend vertically from the surface of the lower structure 11.

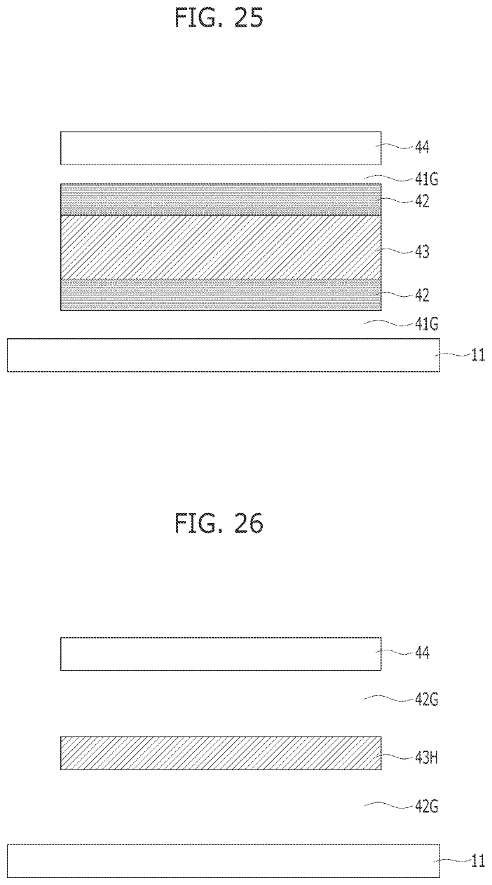

As illustrated in FIG. 25, a plurality of initial horizontal recesses 41G may be formed by selectively removing the sacrificial layers 41. In order to form the plurality of initial horizontal recesses 41G, the sacrificial layers 41 may be selectively removed through the first and second openings 45A and 45B. The initial horizontal recesses 41G may have substantially the same size, for example, the same height.

In order to selectively remove the sacrificial layers 41, a difference in etching selectivity between the sacrificial semiconductor layers 42, the semiconductor layers 43 and the sacrificial layers 41 may be used. The sacrificial layers 41 may be removed using wet etching or dry etching. For example, when each of the sacrificial layers 41 includes a silicon germanium layer and each of the sacrificial semiconductor layers 42 and the semiconductor layer 43 includes a silicon layer, the silicon germanium layers may be etched using an etchant or an etching gas having a selectivity with respect to the silicon layers.

As illustrated in FIG. 26, the sacrificial semiconductor layers 42 and the semiconductor layers 43 may be recessed through the initial horizontal recesses 41G. In order to recess the sacrificial semiconductor layers 42 and the semiconductor layers 43, wet etching or dry etching may be used. In the present embodiment, the semiconductor layers 43 may be partially etched until the sacrificial semiconductor layers 42 are all removed. Accordingly, the thin sacrificial semiconductor layers 42 may all be removed, and the thick semiconductor layers 43 may be thinned as indicated by reference numeral 43H. A recess process for forming the thinned semiconductor layer 43H, that is, the semiconductor layer pattern 43H may be referred to as a thinning process of the semiconductor layers 43. The semiconductor layer patterns 43H may be referred to as a thin-body active layer. The semiconductor layer patterns 43H may each include a single crystal silicon layer. During the formation of the semiconductor layer patterns 43H, the surface of the lower structure 11 may be recessed to a predetermined depth.

By the recess process described above, the semiconductor layer patterns 43H and horizontal recesses 42G may be formed.

As illustrated in FIG. 27, a gate dielectric layer 46 may be formed to fully cover the semiconductor layer patterns 43H. The gate dielectric layer 46 may be formed by a deposition process or an oxidation process. The gate dielectric layer 46 may be made of silicon oxide, silicon nitride, metal oxide, metal oxynitride, metal silicate, high-k material, ferroelectric material, antiferroelectric material, or a combination thereof. The gate dielectric layer 46 may include SiO₂, Si₃N₄, HfO₂, Al₂O₃, ZrO₂, AlON, HfON, HfSiO, HfSiON, or a combination thereof.

In the present embodiment, the gate dielectric layer 46 may be formed by an oxidation process and may be formed to have a uniform thickness on the surfaces of the semiconductor layer pattern 43H.

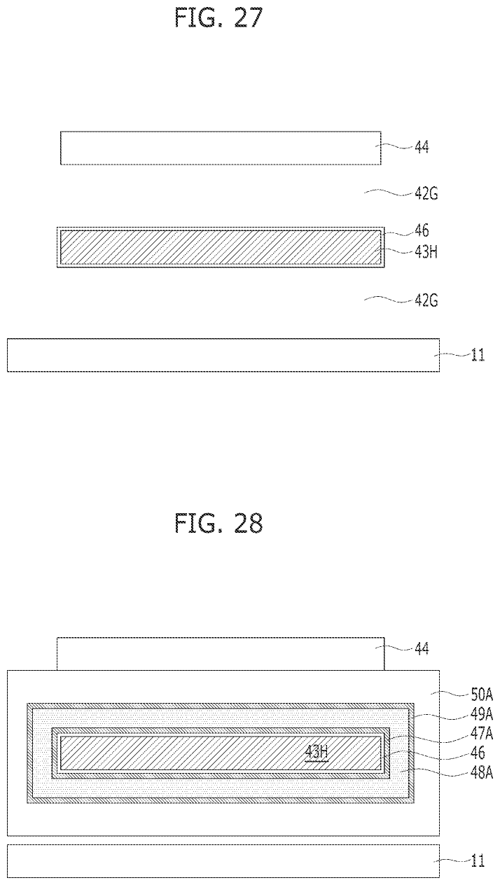

As illustrated in FIG. 28, a plurality of conductive layers may be formed on the gate dielectric layers 46. The conductive layer may include polysilicon, metal, metal nitride, metal carbide, or a combination thereof. The conductive layer may include tungsten, titanium nitride, doped polysilicon, or a combination thereof. In the conductive layer, materials having different work functions may be sequentially deposited.

The plurality of conductive layers may each include a stack of a first liner material 47A, a high work function material 48A, and a second liner material 49A.

The stack of the first liner material 47A, the high work function material 48A, and the second liner material 49A may surround the semiconductor layer pattern 43H on the gate dielectric layer 46.

The first and second liner materials 47A and 49A may each include metal nitride, and the high work function material 48A may include a metal-base high work function material. The first and second liner materials 47A and 49A may each include titanium nitride, and the high work function material 48A may include tungsten.

Subsequently, a cell isolation material 50A may be formed on the second liner material 49A. The cell isolation material 50A may include silicon oxide.

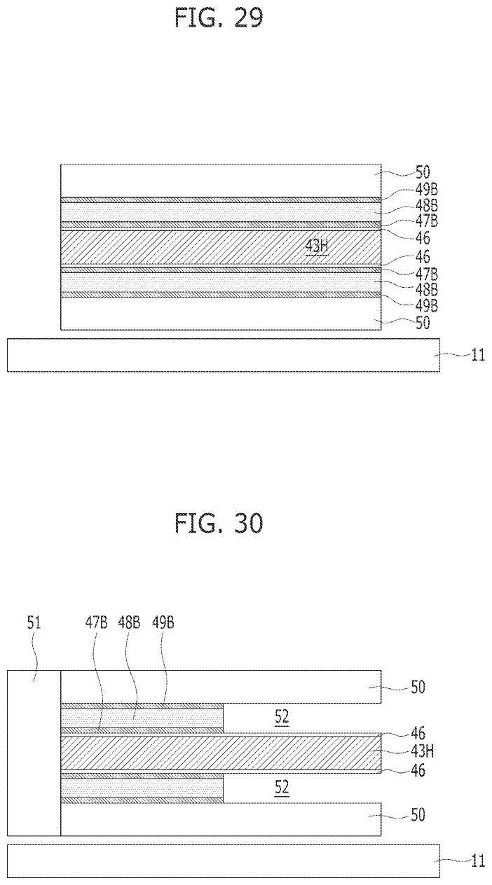

As illustrated in FIG. 29, the first liner material 47A, the high work function material 48A, the second liner material 49A, and the cell isolation material 50A may be selectively recessed. Accordingly, cell isolation layers 50 may be formed above and below the semiconductor layer 43H, respectively, and an inner barrier layer pattern 47B, a high work function material pattern 48B, and an outer barrier layer pattern 49B may be formed between the semiconductor layer 43H and the cell isolation layer 50.

As illustrated in FIG. 30, a first sacrificial gap-fill layer 51 filling the first opening 45A may be formed.

Subsequently, the inner barrier layer pattern 47B, the high work function material pattern 48B, and the outer barrier layer pattern 49B may be horizontally recessed through the second opening 45B to form recesses 52 between the cell separation layers 50 and the semiconductor layer pattern 43H. Even though the recesses 52 are formed, the gate dielectric layer 46 may protect the surfaces of the semiconductor layer pattern 43H.

As illustrated in FIG. 31, a first barrier material 52A and a first sacrificial barrier material 53A may be sequentially formed. The first barrier material 52A may include a metal-base material. The first barrier material 52A may include metal nitride. The second barrier material 52A may include titanium nitride. The first sacrificial barrier material 53A may include polysilicon.

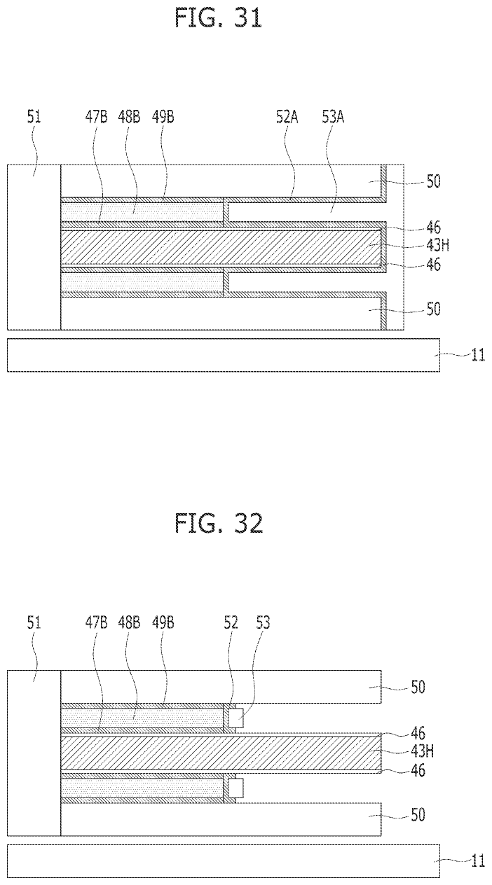

As illustrated in FIG. 32, to form a first sacrificial barrier 53, the sacrificial barrier material 53A may be selectively recessed.

Subsequently, the first barrier material 52A may be selectively etched using the first sacrificial barrier 53 as an etch stopper. Accordingly, a first barrier layer 52 contacting the inner barrier layer pattern 47B, the high work function material pattern 48B, and the outer barrier layer pattern 49B may be formed.

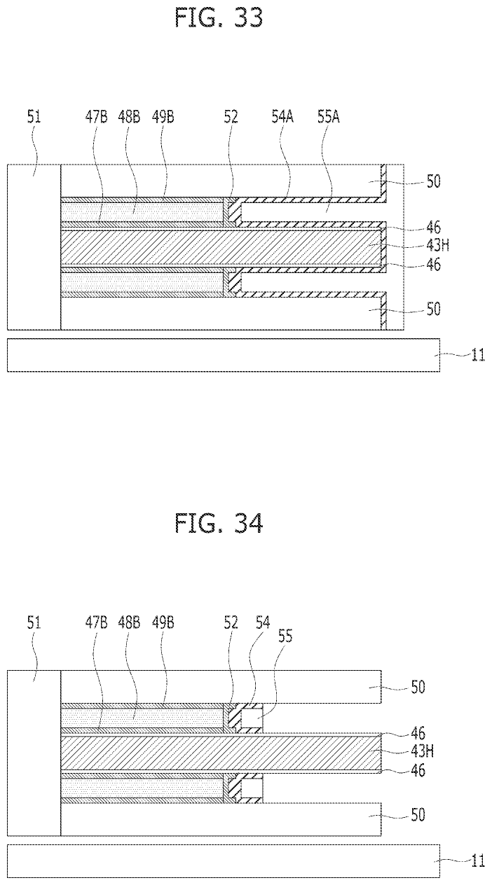

As illustrated in FIG. 33, after the first sacrificial barrier 53 is removed, a first low work function material 54A may be formed on the first barrier layer 52. The first low work function material 54A may be made of a conductive material. The first low work function material 54A may have a work function lower than the mid-gap work function of silicon. For example, the first low work function material 54A may include N-type dopant doped polysilicon. The N-type dopant may include phosphorus (P) or arsenic (As).

A gap-fill material layer 55A may be formed on the second work function material 54A. The gap-fill material layer 55A may include silicon oxide.

As illustrated in FIG. 34, to form a second work function electrode 54 and a gap-fill material 55, the third work function material 54A and the gap-fill material layer 55A may be selectively etched. The third work function electrode 54 may have a bent shape, a cylindrical shape or a rectangular cup shape laterally oriented. The third work function electrode 54 may surround parts of the gap-fill material 55.

The first low work function electrode 54 and the first barrier layer 52 constitute a first electrode G10.

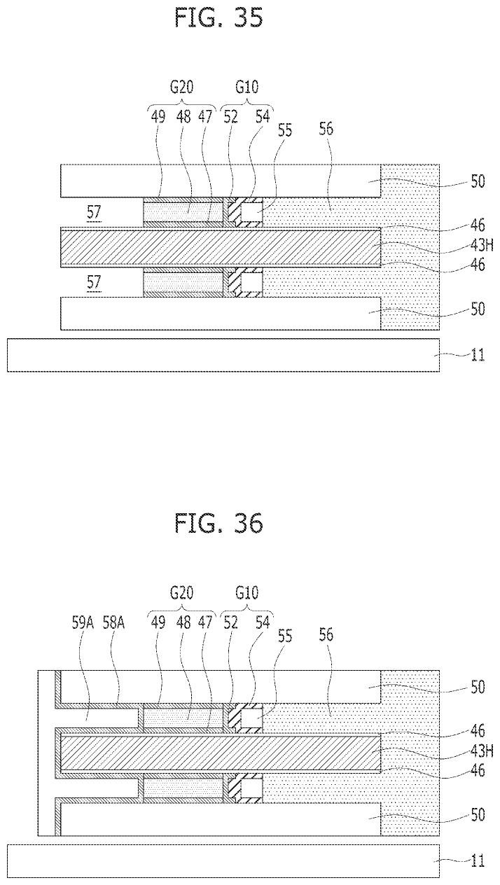

As illustrated in FIG. 35, a second sacrificial gap-fill layer 56 may be formed. The second sacrificial gap-fill layer 56 may include silicon oxide, silicon nitride, or a combination thereof.

Subsequently, after the first sacrificial gap-fill layer 51 is removed, the inner barrier layer pattern 47B, the outer barrier layer pattern 49B, and the high work function material pattern 48B may be horizontally recessed. An inner second barrier layer 47 may be formed by recessing the inner barrier layer pattern 47B, and an outer second barrier layer 49 may be formed by recessing the outer barrier layer pattern 49B. A high work function electrode 48 may be formed by recessing the high work function material pattern 48B.

The inner second barrier layer 47, the high work function electrode 48, and the outer second barrier layer 49 may be vertically stacked in this order, and the stack of these may constitute a second electrode G20.

After the second electrode G20 is formed, horizontal recesses 57 may be defined.

As illustrated in FIG. 36, a third barrier material 58A and a second sacrificial barrier material 59A may be sequentially formed on the second electrode G20. The third barrier material 58A may include a metal-base material. The third barrier material 58A may include metal nitride. The third barrier material 58A may include titanium nitride. The second sacrificial barrier material 59A may include polysilicon.

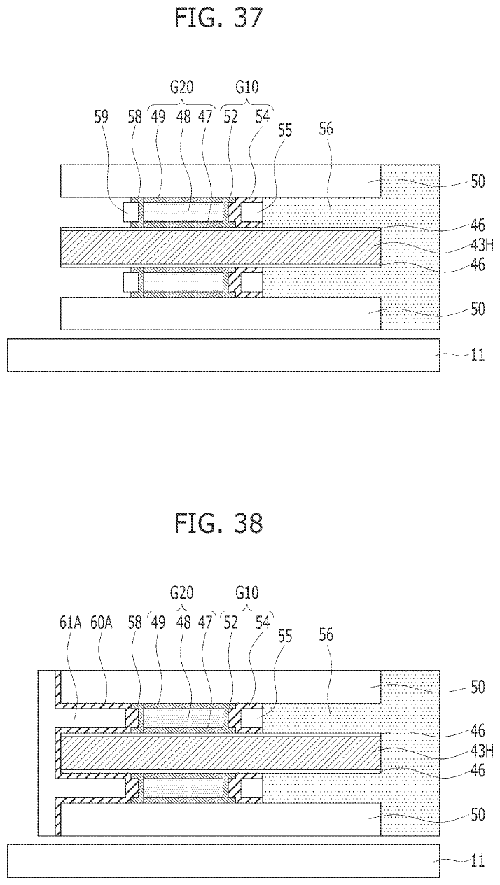

As illustrated in FIG. 37, to form a second sacrificial barrier 59, the second sacrificial barrier material 59A may be selectively recessed.

Subsequently, the third barrier material 58A may be selectively etched using the second sacrificial barrier 59 as an etch stopper. Accordingly, a third barrier layer 58 contacting the high work function electrode 48 and the inner and outer second barrier layers 47 and 49 may be formed.

As illustrated in FIG. 38, after the second sacrificial barrier 59 is removed, a second low work function material 60A may be formed on the third barrier layer 58. The second low work function material 60A may be made of a conductive material. The second low work function material 60A may have a work function lower than the mid-gap work function of silicon. For example, the second low work function material 60A may include N-type dopant doped polysilicon. The N-type dopant may include phosphorus (P) or arsenic (As).

A gap-fill material layer 61A may be formed on the second low work function material 60A. The gap-fill material layer 61A may include silicon oxide.

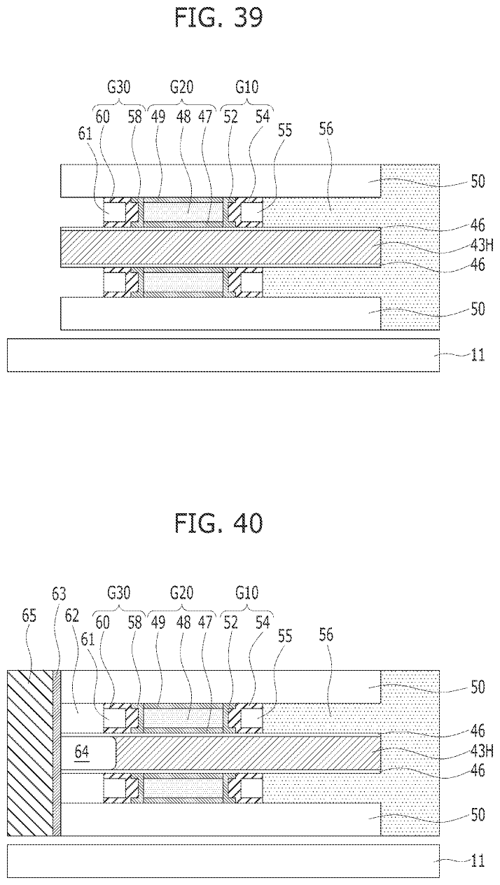

As illustrated in FIG. 39, to form a second low work function electrode 60 and a gap-fill material 61, the second low work function material 60A and the gap-fill material layer 61A may be selectively etched. The second low work function electrode 60 may have a bent shape, a cylindrical shape or a rectangular cup shape laterally oriented. The second low work function electrode 60 may surround parts of the gap-fill material 61.

The third barrier layer 58 and the second low work function electrode 60 may constitute a third electrode G30.

Through a series of processes described above, it is possible to construct second conductive lines having a double structure and vertically opposed to each other with the semiconductor layer 43H interposed therebetween.

In the second conductive line having the double structure, a pair of first electrodes G10, a pair of second electrodes G20, and a pair of third electrodes G30 may be formed. The first electrode G10 may include the first low work function electrode 54 and the first barrier layer 52. The second electrode G20 may include the high work function electrode 48 and the second barrier layers 47 and 49. The third electrode G30 may include the second low work function electrode 60 and the third barrier layer 58.

As illustrated in FIG. 40, a first capping layer 62 may be formed. The first capping layer 62 may include an insulating material. The first capping layer 62 may include silicon oxide, silicon nitride, SiCN, SiCO, SiCON, or a combination thereof.

Subsequently, a first conductive line 65 coupled to the horizontal layer 43H may be formed. The first conductive line 65 may include titanium nitride, tungsten, or a combination thereof. The first conductive line 65 may be a bit line.

Before the first conductive line 65 is formed, a first doped region 64 may be formed at one end of the semiconductor layer 43H. The step of forming the first doped region 64 may include a step of forming a contact node 63 and a step of diffusing impurities from the contact node 63 by performing heat treatment. The contact node 63 may include polysilicon doped with impurities.

Subsequently, a series of processes described with reference to FIG. 19 to FIG. 23 may be performed.

According to the embodiments described above, as a low work function electrode having a bended shape is formed, the length distribution of low work function electrodes can be improved.

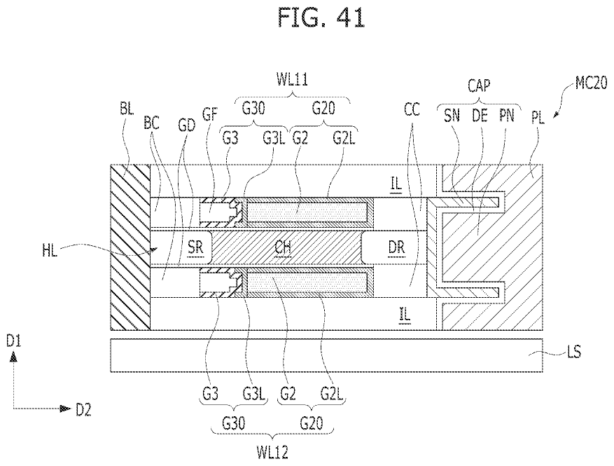

FIG. 41 is a simplified schematic cross-sectional view of a memory cell MC20 in accordance with another embodiment. The memory cell MC20 of FIG. 41 may be similar to the memory cell MC of FIG. 1B. Hereinafter, a detailed description of the overlapping components will refer to FIG. 1A and FIG. 1B.

Referring to FIG. 41, the memory cell MC20 may include a first conductive line BL, a switch element TR, and a data storage element CAP. The switch element TR may include a horizontal layer HL, a gate dielectric layer GD, and a second conductive line DWL. The data storage element CAP may be a memory element such as a capacitor. The first conductive line BL may be a bit line. The second conductive line DWL may be a word line, and the horizontal layer HL may be an active layer. The data storage element CAP may include a first electrode SN, a second electrode, and a dielectric layer DE positioned between the first and second electrodes SN, PN. The switch element TR may include a transistor, and in this case, the second conductive line DWL may serve as a gate electrode. The switch element TR may also be referred to as an access element or a selection element.

The first conductive line BL may vertically extend along a first direction D1. The horizontal layer HL may extend along a second direction D2 intersecting the first direction D1. The second conductive line DWL may extend along a third direction D3 intersecting the first direction D1 and the second direction D2.

The second conductive line DWL may elongate along the third direction D3 and the horizontal layer HL may extend along the second direction D2. The horizontal layer HL may be laterally arranged from the first conductive line BL. The second conductive line DWL may have a double structure. For example, the second conductive line DWL may include upper and lower second conductive lines WL11 and WL12 opposed to each other with the horizontal layer HL interposed therebetween. The gate dielectric layer GD may be formed on an upper surface and a lower surface of the horizontal layer HL. The upper second conductive line WL11 may be disposed above the horizontal layer HL, and the lower second conductive line WL12 may be disposed below the horizontal layer HL. The second conductive line DWL may include a pair of the upper second conductive line WL11 and the lower second conductive line WL12.

The horizontal layer HL may extend along the second direction D2. The horizontal layer HL may include a semiconductor material. For example, the horizontal layer HL may include polysilicon, single crystal silicon, germanium, or silicon-germanium. In another embodiment, the horizontal layer HL may include an oxide semiconductor material. For example, the oxide semiconductor material may include indium gallium zinc oxide (IGZO).

The upper surface and the lower surface of the horizontal layer HL may each have a flat surface. That is, the upper surface and the lower surface of the horizontal layer HL may be parallel to each other along the second direction D2.

The horizontal layer HL may include a channel CH, a first doped region SR between the channel CH and the first conductive line BL, and a second doped region DR between the channel CH and the data storage element CAP. The first doped region SR may be coupled to the first conductive line BL, and the second doped region DR may be coupled to the first electrode SN of the data storage element CAP.

Each of the upper and lower second conductive lines WL11 and WL12 may include a high work function horizontal electrode G20 and a low work function horizontal electrode G30. The high work function horizontal electrode G20 may correspond to the second electrode G20 of the embodiments described above, and the low work function horizontal electrode G30 may correspond to the third electrode G30 of the embodiments described above. In the memory cell MC20, a first electrode G10 may be omitted.

The high work function horizontal electrode G20 may include a high work function electrode G2 and a covered barrier layer G2L, and the low work function electrode G30 may include a low work function electrode G3 and a vertical barrier layer G3L.

Each of the upper and lower second conductive lines WL11 and WL12 may include the high work function electrode G2 and the low work function electrode G3. The high work function electrode G2 and the low work function electrode G3 may be horizontally disposed along the second direction D2. The low work function electrode G3 may be adjacent to the first conductive line BL, and the high work function electrode G2 may be adjacent to the data storage element CAP.

The high work function electrode G2 and the low work function electrode G3 may each include a semiconductor material, titanium nitride, tungsten, molybdenum, ruthenium, polysilicon, or a combination thereof.

The high work function electrode G2 and the low work function electrode G3 may be made of materials having different work functions. The high work function electrode G2 may have a higher work function than the low work function electrode G3. The high work function electrode G2 may include a high work function material. The high work function electrode G2 may have a work function higher than the mid-gap work function of silicon. The low work function electrode G3 may include a low work function material. The low work function electrode G3 may have a work function lower than the mid-gap work function of silicon. Additionally, the high work function material may have a work function higher than 4.5 eV, and the low work function material may have a work function lower than 4.5 eV. The high work function electrode G2 may include a metal-base material, and the low work function electrodes G1 and G3 may each include a semiconductor material.

The low work function electrode G3 may include N-type dopant doped polysilicon. The high work function electrode G2 may include metal, metal nitride, or a combination thereof. The high work function electrode G2 may include tungsten, titanium nitride, molybdenum, ruthenium, or a combination thereof.

In the present embodiment, each of the upper and lower second conductive lines WL11 and WL12 of the second conductive line DWL may be horizontally disposed along the second direction D2 in the order of the low work function electrode G3 and the high work function electrode G2. The high work function electrode G2 may include metal, and the low work function electrode G3 may include polysilicon.

Each of the upper and lower second conductive lines WL11 and WL12 of the second conductive line DWL may have a poly Si-metal (PM) structure horizontally disposed along the second direction D2. In the PM structure, the high work function electrode G2 may be a metal-base material, and the low work function electrode G3 may be N-type dopant doped polysilicon. The N-type dopant may include phosphorus or arsenic.

The covered barrier layer G2L may be disposed on each of an upper surface and a lower surface of the high work function electrode G2. The vertical barrier layer G3L may be disposed between the high work function electrode G2 and the low work function electrode G3. The covered barrier layer G2L and the vertical barrier layer G3L may be electrically connected to each other.

The covered barrier layer G2L and the vertical barrier layer G3L may each include titanium nitride, tantalum nitride, tungsten nitride, or molybdenum nitride.

The covered barrier layer G2L may have a bent shape, a cylindrical shape or a rectangular cup shape laterally oriented covering a part of the upper surface, the lower surface, and one side surface of the high work function electrode G2. The vertical barrier layer G3L may have a bent shape, a cylindrical shape or a rectangular cup shape laterally oriented covering a part of an outer surface of the low work function electrode G3.

The low work function electrodes G1 and G3 may each have a bent shape or a rectangular cup shape laterally oriented.

The low work function electrode G3 may include an inner surface covering a gap-fill material GF and the outer surface contacting the vertical barrier layer G3L. The vertical barrier layer G3L may have a bent shape, a cylindrical shape or a rectangular cup shape laterally oriented covering a part of the outer surface of the low work function electrode G3.

As described above, the first and lower second conductive lines WL11 and WL12 may each have a double electrode structure including the high work function electrode G2 and the low work function electrode G3. The second conductive line DWL may include a pair of high work function electrodes G2 across the horizontal layer HL with the horizontal layer HL interposed therebetween and a pair of low work function electrodes G3 across the horizontal layer HL with the horizontal layer HL interposed therebetween. The high work function electrodes G2 of the second conductive line DWL may vertically overlap with the channel CH, and the low work function electrodes G3 of the second conductive line DWL may vertically overlap the first doped region SR of the horizontal layer.

As the high work function electrode G2 is disposed at the center of the second conductive line DWL, and the low work function electrode G3 adjacent to the first conductive line BL is disposed, leakage current such as gate induced drain leakage (GIDL) can be reduced.

As the high work function electrode G2 is disposed at the center of the second conductive line DWL, the threshold voltage of the switch element TR may be increased. Since the low work function electrode G3 of the second conductive line DWL has a low work function, a low electric field may be formed between the first conductive line BL and the second conductive line DWL.

The present disclosure described above is not limited by the aforementioned embodiment and the accompanying drawings, and it will be obvious to those skilled in the art to which the present disclosure pertains that various replacements, modifications, and changes can be made without departing from the technical spirit of the present disclosure.

What is claimed is:

1. A semiconductor device comprising:
a horizontal layer spaced apart from a lower structure to extend along a direction parallel to the lower structure;
a first conductive line extending along a direction perpendicular to the lower structure and coupled to one end of the horizontal layer;
a data storage element coupled to the other end of the horizontal layer; and
a second conductive line extending along a direction across the horizontal layer,
wherein the second conductive line comprises:
a high work function electrode; and
a low work function electrode having a cup shape laterally oriented and positioned adjacent to the first conductive line and having a lower work function than the high work function electrode.

2. The semiconductor device of claim 1, further comprising:
a covered barrier layer covering an upper surface, a lower surface, and one side surface of the high work function electrode; and
a vertical barrier layer between the other side surface of the high work function electrode and the low work function electrode.

3. The semiconductor device of claim 1, wherein the low work function electrode includes an outer surface opposed to the high work function electrode and a bended inner surface opposed to the first conductive line.

4. The semiconductor device of claim 3, further comprising:
a gap-fill material disposed on the inner surface of the low work function electrode.

5. The semiconductor device of claim 1, further comprising:
a gap-fill material disposed on an inner surface of the low work function electrode.

6. The semiconductor device of claim 1, wherein the low work function electrode includes N-type dopant doped polysilicon.

7. The semiconductor device of claim 1, wherein the high work function electrode includes metal, metal nitride, or a combination thereof.

8. The semiconductor device of claim 1, wherein the horizontal layer includes a single crystal semiconductor material, a polycrystalline semiconductor material, or an oxide semiconductor material.

9. The semiconductor device of claim 1, wherein the horizontal layer comprises:
a first doped region coupled to the first conductive line;
a second doped region coupled to the data storage element; and
a channel between the first doped region and the second doped region.

10. The semiconductor device of claim 1, wherein the second conductive line includes a double structure and opposed to each other with the horizontal layer interposed therebetween.

11. The semiconductor device of claim 1, wherein the data storage element includes a capacitor, and the capacitor includes a cylindrical first electrode, a second electrode, and a dielectric layer between the first electrode and the second electrode.

12. The semiconductor device of claim 1, further comprising:
a gate dielectric layer fully covering each of an upper surface and a lower surface of the horizontal layer.

13. The semiconductor device of claim 1, further comprising:
an additional low work function electrode adjacent to the data storage element and having a lower work function than the high work function electrode.
